(19) United States
(12) Patent Application Publication
(10) Pub. No.: US 2024/0114738 A1
(43) Pub. Date: Apr. 4, 2024

(54) DISPLAY PANEL AND DISPLAY APPARATUS

(71) Applicant: WUHAN TIANMA MICRO-ELECTRONICS CO., LTD., Wuhan (CN)

(72) Inventor: Yuehua YANG, Wuhan (CN)

(73) Assignee: WUHAN TIANMA MICRO-ELECTRONICS CO., LTD., Wuhan (CN)

(21) Appl. No.: 18/541,300

(22) Filed: Dec. 15, 2023

(30) Foreign Application Priority Data
Jan. 20, 2023 (CN) 202310096485.8

(51) Int. Cl. H10K 59/131

(52) U.S. Cl. CPC H10K 59/131

(57) ABSTRACT

A display panel and a display apparatus are provided, which relates to display technical field. In an embodiment, the display panel includes a display area and light transmission area. In an embodiment, the display area includes: signal lines arranged along first direction and extending along second direction; connecting lines configured to electrically connect signal lines located at two sides of light transmission area along second direction, wherein connecting lines include type-I connecting lines, and at least part of type-I connecting lines are located in display area; type-I connecting lines include edge connecting line which, as one of the type-I connecting lines, has maximum distance from light transmission area; and common lines including type-I common lines, wherein at least part of type-I common lines are located in display area, and part of type-I common lines are located at a side of edge connecting line adjacent to light transmission area.

### CROSS-REFERENCE TO RELATED DISCLOSURE

The present disclosure claims priority to Chinese Patent Disclosure No. 202310096485.8, filed on Jan. 20, 2023, the content of which is incorporated herein by reference in its entirety.

### TECHNICAL FIELD

The present disclosure relates to the field of display technologies, and, in particular, relates to a display panel and a display apparatus.

### BACKGROUND

With the increasing requirements of users' diversified design for display panels, there is a solution to dispose a through hole in a display area of the display panel to dispose components such as a camera. Since the through hole disposed inside the display area will disconnect part of the signal line, researchers have focused on how to connect the signal line disconnected by the through hole and how to ensure the display consistency between the area around the through hole and other areas when the through hole is disposed in the display area.

### SUMMARY

A first aspect of the present disclosure provides a display panel. In an embodiment, the display panel includes a display area and a light transmission area at least partially surrounded by the display area. In an embodiment, the display area includes: signal lines arranged along a first direction and extending along a second direction, wherein the first direction intersects with the second direction; connecting lines configured to electrically connect the signal lines located at two sides of the light transmission area along the second direction, wherein the connecting lines include type-I connecting lines, and at least one of the type-I connecting lines is located in the display area; the type-I connecting lines include an edge connecting line, and the edge connecting line is one type-I connecting line having a maximum distance from the light transmission area; and common lines including type-I common lines, wherein at least one of the type-I common lines is located in the display area, and part of the type-I common lines is located at a side of the edge connecting line adjacent to the light transmission area.

A second aspect of the present disclosure provides a display apparatus including the display panel described in the first aspect.

### BRIEF DESCRIPTION OF DRAWINGS

In order to more clearly illustrate technical solutions of embodiments of the present disclosure, the accompanying drawings used in the embodiments are briefly described below. The drawings described below are merely a part of the embodiments of the present disclosure. Based on these drawings, those skilled in the art can obtain other drawings.

FIG. 1 is a schematic diagram of a display panel according to an embodiment of the present disclosure;

FIG. 2 is a simplified schematic diagram of signal lines and a type-I connecting line in an area Q1 shown in FIG. 1 according to an embodiment of the present disclosure;

FIG. 3 is a simplified schematic diagram of common lines and connecting lines in an area Q1 shown in FIG. 1 according to an embodiment of the present disclosure;

FIG. 4 is an equivalent circuit diagram of a sub-pixel according to an embodiment of the present disclosure;

FIG. 5 is a simplified and enlarged schematic diagram of an area Q2 shown in FIG. 3 according to an embodiment of the present disclosure;

FIG. 6 is a wiring diagram corresponding to FIG. 5 according to an embodiment of the present disclosure;

FIG. 7 is a top view of a semiconductor layer shown in FIG. 6 according to an embodiment of the present disclosure;

FIG. 8 is a top view of a first metal layer shown in FIG. 6 according to an embodiment of the present disclosure;

FIG. 9 is a top view of a second metal layer shown in FIG. 6 according to an embodiment of the present disclosure;

FIG. 10 is a top view of a third metal layer shown in FIG. 6 according to an embodiment of the present disclosure;

FIG. 11 is a top view of a fourth metal layer shown in FIG. 6 according to an embodiment of the present disclosure;

FIG. 12 is a top view of a fifth metal layer shown in FIG. 6 according to an embodiment of the present disclosure;

FIG. 13 is a sectional view of a display area of a display panel according to an embodiment of the present disclosure;

FIG. 14 is a simplified and enlarged diagram of an area Q3 shown in FIG. 3 according to an embodiment of the present disclosure;

FIG. 15 is a partial enlarged schematic diagram of a display panel according to another embodiment of the present disclosure;

FIG. 16 is a simplified enlarged schematic diagram of an area Q4 shown in FIG. 15 according to an embodiment of the present disclosure;

FIG. 17 is a simplified enlarged schematic diagram of area Q5 shown in FIG. 15 according to an embodiment of the present disclosure;

FIG. 18 is a partial enlarged schematic diagram of a display panel according to another embodiment of the present disclosure;

FIG. 19 is a simplified enlarged diagram of a second non-display area shown in FIG. 18 according to an embodiment of the present disclosure;

FIG. 20 is a wiring diagram corresponding to FIG. 19 according to an embodiment of the present disclosure;

FIG. 21 is a top view of the fourth metal layer shown in FIG. 19 according to an embodiment of the present disclosure;

FIG. 22 is a sectional view of a second non-display area of a display panel according to an embodiment of the present disclosure;

FIG. 23 is a top view of the fifth metal layer shown in FIG. 19 according to an embodiment of the present disclosure;

FIG. 24 is a sectional view of a second non-display area according to another embodiment of the present disclosure;

FIG. 25 is a partial enlarged schematic diagram of a display panel according to another embodiment of the present disclosure;

FIG. 26 is a partial enlarged schematic diagram of a display panel according to another embodiment of the present disclosure;

FIG. 27 is a partial enlarged schematic diagram of a display panel according to another embodiment of the present disclosure;

FIG. 28 is a sectional view along BB′ shown in FIG. 27 according to an embodiment of the present disclosure;

FIG. 29 is a schematic diagram of local enlargement of a display panel according to another embodiment of the present disclosure;

FIG. 30 is a simplified enlarged schematic diagram of an area Q6 shown in FIG. 29 according to an embodiment of the present disclosure;

FIG. 31 is an enlarged schematic diagram of an area Q7 shown in FIG. 1 according to an embodiment of the present disclosure; and

FIG. 32 is a schematic diagram of a display apparatus according to an embodiment of the present disclosure.

### DESCRIPTION OF EMBODIMENTS

In order to better understand technical solutions of the present disclosure, the embodiments of the present disclosure are described in detail with reference to the drawings.

It should be clear that the described embodiments are merely part of the embodiments of the present disclosure rather than all of the embodiments. All other embodiments obtained by those skilled in the art shall fall into the protection scope of the present disclosure.

The terms used in the embodiments of the present disclosure are merely for the purpose of describing specific embodiment, rather than limiting the present disclosure. The terms “a”, “an”, “the” and “said” in a singular form in an embodiment of the present disclosure and the attached claims are also intended to include plural forms thereof, unless noted otherwise.

It should be understood that the term “or” used in the context of the present disclosure is to describe a correlation relation of related objects, indicating that there can be three relations, e.g., A or B can indicate only A, both A and B, and only B. In addition, the symbol “/” in the context generally indicates that the relation between the objects before and after the “/” is an “or” relation.

It should be understood that although the terms ‘first’, ‘second’ and ‘third’ can be used in the present disclosure to describe common lines, these common lines should not be limited to these terms. These terms are used only to distinguish common lines from each other. For example, without departing from the scope of the embodiments of the present disclosure, a first common line can also be referred to as a second common line. Similarly, the second common line can also be referred to as the first common line.

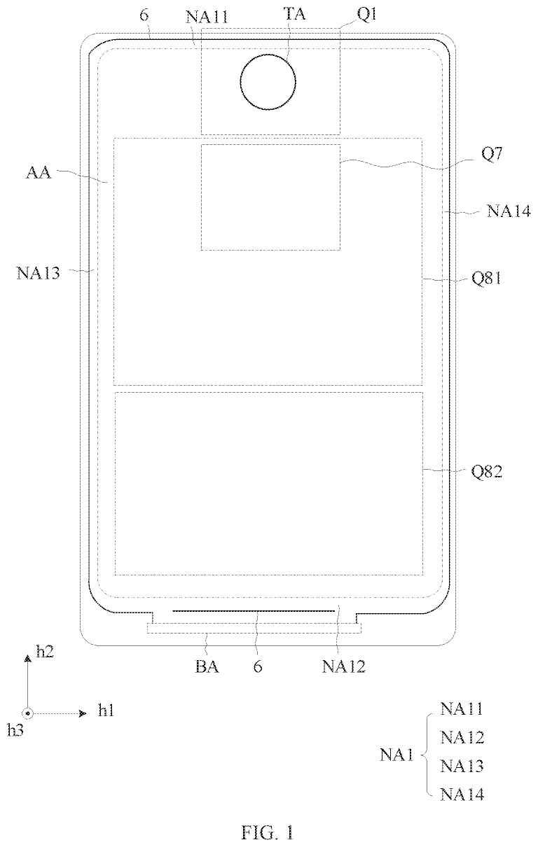

The present disclosure provides a display panel. FIG. 1 is a schematic diagram of a display panel according to an embodiment of the present disclosure. As shown in FIG. 1, the display panel includes a display area AA, a light transmission area TA, and a first non-display area NA1. The display area AA at least partially surrounds the light transmission area TA. The first non-display area NA1 at least partially surrounds the display area AA.

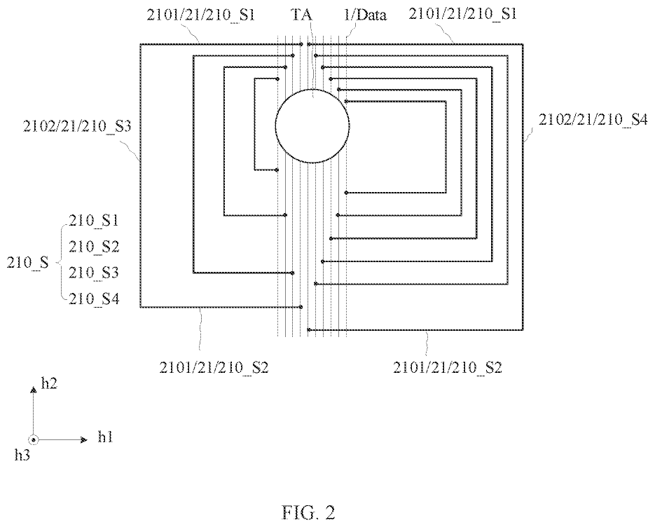

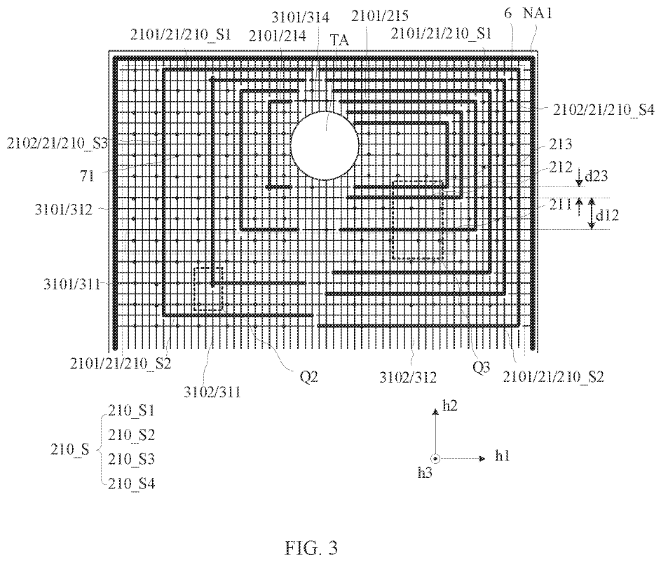

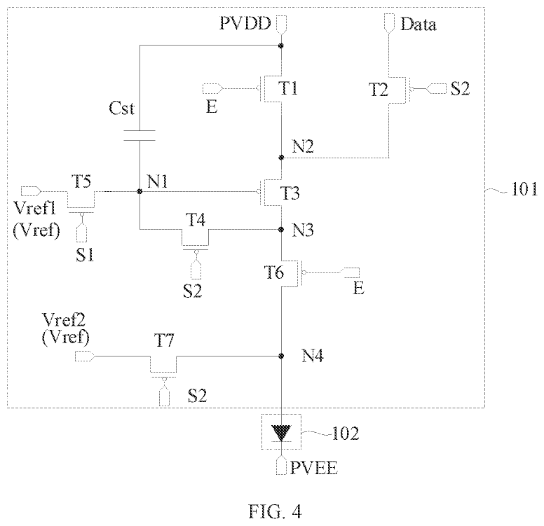

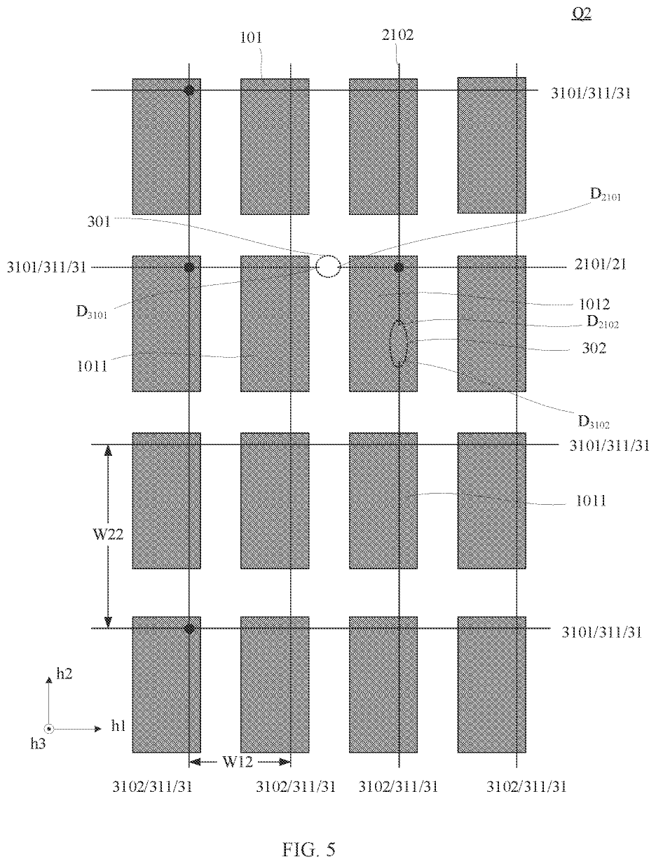

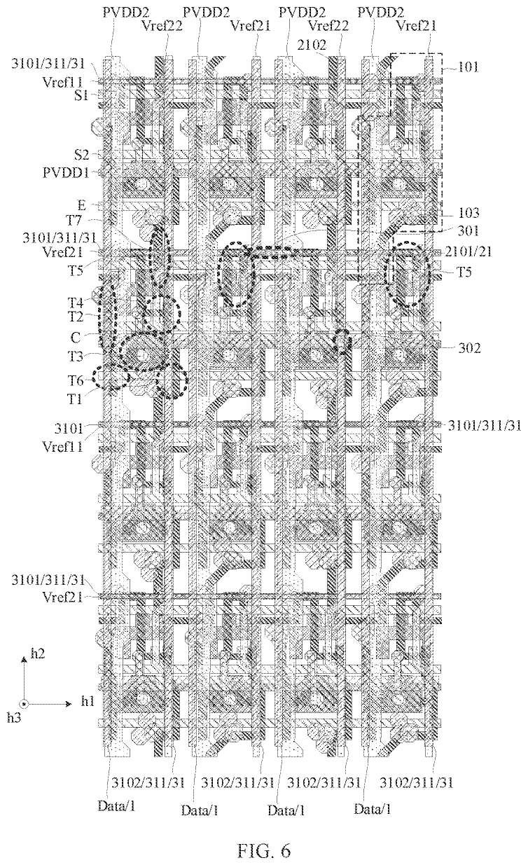

The display area AA includes multiple sub-pixels. FIG. 2 is a simplified schematic diagram of signal lines and a type-I connecting line in an area Q1 shown in FIG. 1; FIG. 3 is a simplified schematic diagram of common lines and connecting lines in an area Q1 shown in FIG. 1; FIG. 4 is an equivalent circuit diagram of a sub-pixel according to an embodiment of the present disclosure; FIG. 5 is a simplified and enlarged schematic diagram of an area Q2 shown in FIG. 3 according to an embodiment of the present disclosure; and FIG. 6 is a wiring diagram corresponding to FIG. 5 according to an embodiment of the present disclosure. As shown in FIG. 2 to FIG. 6, the sub-pixel includes a pixel driving circuit 101 and a light-emitting element 102 that are electrically connected. The pixel driving circuit 101 includes a first transistor T1, a second transistor T2, a third transistor T3, a fourth transistor T4, a fifth transistor T5, a sixth transistor T6, a seventh transistor T7 and a storage capacitor Cst. The third transistor T3 is a drive transistor.

As shown in FIG. 4, the display area AA further includes a first scan line S1, a second scan line S2, a light-emitting control signal line E, a data line Data, a first supply voltage line PVDD, a second supply voltage line PVEE (not shown in FIG. 6), a first reference voltage signal line Vref1 and a second reference voltage signal line Vref2.

The first transistor T1 is configured to electrically connect the first supply voltage line PVDD and the second node N2 under the control of the light-emitting control signal line E. The second transistor T2 is configured to electrically connect the data line Data to the second node N2 under the control of the second scan line S2. The third transistor T3 is configured to electrically connect the second node N2 and the third node N3 under the control of the first node N1. The fourth transistor T4 is configured to electrically connect the third node N3 and the first node N1 under the control of the second scan line S2. The fifth transistor T5 is configured to electrically connect the first reference voltage signal line Vref1 and the first node N1 under the control of the first scan line S1. The sixth transistor T6 is configured to electrically connect the third node N3 and the fourth node N4 under the control of the light-emitting control signal line E. The seventh transistor T7 is configured to electrically connect the second reference voltage signal line Vref2 and the fourth node N4 under the control of the second scan line S2. A first electrode of the light-emitting element 102 is electrically connected to the fourth node N4, and a second electrode of the light-emitting element 102 is electrically connected to the second supply voltage line PVEE. A first electrode plate of the storage capacitor Cst is electrically connected to the first supply voltage line PVDD, and a second electrode plate of the storage capacitor Cst is electrically connected to the first node N1.

An operating process of the pixel driving circuit 101 includes a reset stage, a charging stage and a light-emitting stage. In the reset stage, the first scan line S1 controls the fifth transistor T5 to be turned on, and a first reference voltage provided by the first reference voltage signal line Vref1 reset the first node N1 through the fifth transistor T5. In the charging stage, the second scan line S2 controls the second transistor T2, the fourth transistor T4 and the seventh transistor T7 to be turned on, and a data voltage V_{data} provided by the data line Data is written to the second node N2 through the second transistor T2. At this stage, the third transistor T3 is turned on. The potential of the first node N1 changes continuously until the potential V_{N1} of the first node N1 is changed to V_{N1}=V_{data}−|Vₜₕ|, where Vdata is a data voltage provided by the data line Data, and Vₜₕ is a threshold voltage of the third transistor T3. The second reference voltage provided by the second reference voltage signal line Vref2 resets the fourth node N4 through the seventh transistor T7. In the light-emitting stage, the first transistor T1, the sixth transistor T6 and the third transistor T3 are turned on. Under the action of the first supply voltage provided by the first supply voltage line PVDD and the second supply voltage line PVEE, a current path between the first supply voltage line PVDD and the second supply voltage line PVEE is turned on, and the light-emitting element 102 electrically connected to the pixel driving circuit 101 is lightened.

Exemplarily, the first reference voltage and second reference voltage described above can be different or can be the same. When the first reference voltage and the second reference voltage are the same, the first reference voltage signal line Vref1 and the second reference voltage signal line Vref2 can be collectively called as “reference voltage signal line”. The first reference voltage and the second reference voltage transmitted by the first reference voltage signal line Vref1 and the second reference voltage signal line Vref2 respectively can be collectively called as “reference voltage”. That is, the fifth transistor T5 and the seventh transistor T7 can both be connected to the reference voltage signal line so as to reset the first node N1 and the fourth node N4 with a same reference voltage. In the following embodiments of the present disclosure, the first reference voltage and the second reference voltage are different, unless otherwise specified.

Optionally, as shown in FIG. 6, the first scan line S1, the second scan line S2, and the light-emitting control signal line E all extend along a first direction h1, and are arranged along a second direction h2. The first direction h1 intersects in the second direction h2. FIG. 6 schematically shows that the first direction h1 is perpendicular to the second direction h2. Multiple pixel driving circuits 101 are arranged in an array in the first direction h1 and the second direction h2. One first scan line S1, one second scan line S2, and one light-emitting control signal line E are all electrically connected to multiple pixel driving circuits 101 arranged along the first direction h1. The data line Data extends along the second direction h2, and multiple data lines Data are arranged along the first direction h1. One data line Data is electrically connected to multiple pixel driving circuits 101 arranged along the second direction h2. The specific wiring in the display area AA will be explained in the following text, which will not be repeated here.

Exemplarily, in the embodiments of the present disclosure, the first supply voltage, the second supply voltage, the first reference voltage and the second reference voltage that are required for operation of pixel driving circuit 101 can be the same. That is, the first supply voltage transmitted by the first supply voltage line PVDD, the second supply voltage transmitted by the second supply voltage line PVEE, the first reference voltage transmitted by the first reference voltage signal line Vref1 and the second reference voltage transmitted by the second reference voltage signal line Vref2 can be a common voltage shared by multiple pixel driving circuits 101.

In some embodiments of the present disclosure, the light transmission area TA includes a through hole or a blind hole. The above sub-pixel and/or signal line are not disposed in the light transmission area TA to improve the light transmittance of the light transmission area TA. Exemplarily, subsequently, the display panel can be disposed with a photosensitive element such as a camera and an iris sensor, and an orthogonal projection of the photosensitive element on a plane of the display panel is at least partially located in the light transmission area TA, external ambient light can pass through the light transmission area TA and then enter the photosensitive element.

Optionally, as shown in FIG. 2, the display panel includes a signal line 1. Part of the signal line 1 can be disconnected by the light transmission area TA. That is, an extension line of part of the signal line 1 can pass through the light transmission area TA. The display panel further includes multiple connecting lines which are configured to connect the signal lines 1 located at two sides of the transmission area TA along the extension direction of the signal line 1.

Exemplarily, at least one of the first scan line S1, the second scan line S2, the light-emitting control signal line E and the data line Data described above includes the signal line 1 which can be disconnected by the transmission area TA. FIG. 2 schematically shows that the data line Data includes the signal line 1. When the data line Data includes the signal line 1, i.e., when the signal line 1 extends along the second direction h2, the connecting line 2 is configured to connect the signal lines 1 located at two sides of the light transmission area TA along the second direction h2. The two signal lines 1 connected by the connecting line 2 are electrically connected to multiple pixel driving circuits 101 arranged along the second direction h2.

In some embodiments of the present disclosure, the connecting line includes multiple type-I connecting lines 21, at least part of the multiple type-I connecting lines 21 is located in the display area AA. Exemplarily, as shown in FIG. 2, the type-I connecting line 21 includes at least two first connecting sub-lines 2101 and a second connecting sub-line 2102 located between two adjacent first connecting sub-lines 2101. The first connecting sub-line 2101 and the second connecting sub-line 2102 cross to be electrically connected. Optionally, the first connecting sub-line 2101 extends in the first direction h1. The second connecting sub-line 2102 extends in the second direction h2.

At least part of the type-I connecting line 21 is located in the display area AA, that is, at least part of the at least one of the first connecting sub-line 2101 and the second connecting sub-line 2102 is located in the display area AA. In this way, it is not only ensure that the signal line 1 disconnected by the transmission area TA can receive signals normally, but also reduce the number of connecting lines disposed between the transmission area TA and the display area AA, which is conducive to reducing the width of the non-display area surrounding the transmission area TA.

The type-I connecting line 21 includes an edge connecting line 210_S, and the edge connecting line 210_S is a type-I connecting line 21 with a largest distance to the transmission area TA. In other words, the edge connecting line 210_S is a type-I connecting line 21 with a minimum distance to the first non-display area NA1.

Exemplarily, the display panel AA can include multiple edge connecting lines 210_S located at different positions. Different edge connecting lines 210_S are located at different positions adjacent to the first non-display area NA1.

When the first connecting sub-line 2101 and the second connecting sub-line 2102 are both disposed in the display area AA, taking a quadrilateral shape design of an outer contour of the display area AA as an example, as shown in FIG. 1, the first non-display area NA1 includes a first non-display sub-area NA11, a second non-display sub-area NA12, a third non-display sub-area NA13 and a fourth non-display sub-area NA14. The first non-display sub-area NA11 and the second non-display sub-area NA12 are located at two sides of the display area AA in the second direction h2. The third non-display sub-area NA13 and the fourth non-display sub-area NA14 are located at two sides of the display area AA in the first direction h1. As shown in FIG. 1 and FIG. 2, one of first connecting sub-lines 2101 of the type-I connecting line 21 is located between the light transmission area TA and the first non-display sub-area NA11, and the other one of first connecting sub-lines 2101 of the type-I connecting line 21 is located between the light transmission area TA and the second non-display sub-area NA12. The second connecting sub-line 2102 of the type-I connecting line 21 is located between the light transmission area TA and the third non-display sub-area NA13, or located between the light transmission area TA and the fourth non-display sub-area NA14. In FIG. 2 schematically shows that part of the second connecting sub-lines 2102 of the type-I connecting line 21 is located between the transmission area TA and the third non-display sub-area NA13, and other parts of the second connecting sub-lines 2102 of the type-I connecting line 21 are located between the transmission area TA and the fourth non-display sub-area NA14.

Accordingly, as shown in FIG. 1 and FIG. 2, the edge connecting line 210_S includes a first edge connecting line 210_S1, a second edge connecting line 210_S2, a third edge connecting line 210_S3 and a fourth edge connecting line 210_S4. The first edge connecting line 210_S1 is located between the light transmission area TA and the first non-display sub-area NAIL the second edge connecting line 210_S2 is located between the light transmission area TA and the second non-display sub-area NA12, and the third edge connecting line 210_S3 is located between the light transmission area TA and the third non-display sub-area NA13. The fourth edge connecting line 210_S4 is located between the light transmission area TA and the fourth non-display sub-area NA14.

Exemplarily, the first edge connecting 210_S1 can be electrically connected to the third edge connecting 210_S3 or the fourth edge connecting 210_S4, and/or the second edge connecting 210_S2 can be electrically connected to the third edge connecting 210_S3 or the fourth edge connecting 210_S4. Alternatively, the first edge connecting 210_S1 can be insulated from the third edge connecting 210_S3 or the fourth edge connecting 210_S4, and/or the second edge connecting 210_S2 can be insulated from the third edge connecting 210_S3 or the fourth edge connecting 210_S4.

Exemplarily, as shown in FIG. 2 and FIG. 3, the display panel can include at least two first edge connecting lines 210_S1 and/or at least two second edge connecting lines 210_S2, in which two first edge connecting lines 210_S1 are electrically connected to different signal lines 1, and, two second connecting sub-lines 2102 connected to these two first edge connecting lines 210_S1 are respectively located at two sides of the light transmission area TA in the first direction h1. Two second edge connecting lines 210_S2 are electrically connected to different signal lines 1. Moreover, the two second connecting sub-lines 2102 connected to these two second edge connecting lines 210_S2 are respectively located at two sides of the light transmission area TA in the first direction h1.

The display panel further includes a common lines. Exemplarily, the common line can be configured to transmit a common voltage. Optionally, the common voltage includes any of the first supply voltage, second supply voltage, and reference voltage described above. Disposing the common line can reduce voltage drop of the common voltage and improve brightness consistency of the sub-pixels at different positions.

As shown in FIG. 3, the common line includes a type-I common line 31. At least part of the type-I common line 31 is located in the display area AA, and at least part of the type-I common line 31 is located at a side of the edge connecting line 210_S adjacent to the light transmission area TA. It should be noted that the lines with different widths in FIG. 2 and FIG. 3 representing the signal line 1, the type-I common line 31 and type-I connecting line 21 are only configured to distinguish various trace lines and do not represent an actual width of the trace lines.

In the embodiments of the present disclosure, by disposing a light transmission area TA in the display panel, subsequently a photosensitive element can be disposed by corresponding to the light transmission area TA, so that the display panel can have functions of shooting or biometric identification and enrich user's experience.

Moreover, in the embodiments of the present disclosure, by disposing the type-I connecting line 21 at least part of the which is located in the display area AA, the type-I connecting line 21 is configured to connect the signal lines 1 located at two sides of the light transmission area TA along the extension direction of signal line 1, based on ensuring the light transmittance of the light transmission area TA, and, ensuring normal driving of pixel driving circuits 101 connected by signal lines 1 at two sides of the transmission area TA along the extension direction of signal line 1, the number of connecting lines surrounding the transmission area TA can be reduced, so as to reduce the width of non-display area between the transmission area TA and the display area AA, which is conducive to improving the visual effect of the display panel.

Exemplarily, as shown in FIG. 1, the display panel further includes a binding area BA. The binding area BA includes a bonding pad. A drive chip is bound to the bonding pad. There is a large distance between the light transmission area TA and the binding area BA is large, that is, when the light transmission area TA is disposed at a position far away from the binding area BA, in the embodiments of the present disclosure, a common line for transmitting a common voltage is disposed, the common line includes a type-I common line 31 at least partially located in the display area AA, and part of the type-I common line 31 is located at a side of the edge connecting line 210_S adjacent to the light transmission area TA, so that a conducting path of the common voltage between the edge connecting line 210_S and the light transmission area TA can be increased, which is conducive to reducing the common voltage in the area far from the binding area BA, for example, the voltage drop in the area between the edge connecting line 210_S and the light transmission area TA, which can improve the display consistency between the position adjacent to the drive chip and the position far away from the drive chip in the display area AA.

In addition, the external ambient light can be reflected by the type-I common line 31 and the type-I connecting line 21 after it is incident to the display panel. Compared with the case in which no type-I common line 31 is disposed, based on the configuration manner provided by the embodiments of the present disclosure, it can further improve the reflection consistency of the ambient light between the position of the display area AA where the type-I connecting line 21 is disposed and the position of the display area AA where the type-I connecting line 21 is not disposed.

Exemplarily, as shown in FIG. 5 and FIG. 6, along the direction h3 perpendicular to the plane of the display panel, in the embodiments of the present disclosure, at least part of the type-I connecting line 21 or at least part of the type-I common line 31 can overlap with the pixel driving circuit 101. Such configuration can reduce the shielding of the light transmission area in the display area AA by the type-I connecting line 21 or the type-I common line 31, which is conducive to increasing the light transmission area of the display area AA. When the display panel cooperates with a fingerprint recognition module to make the display panel have a function of fingerprint recognition, the light intensity entering the fingerprint recognition module can be guaranteed, so as to ensure the accuracy of fingerprint recognition.

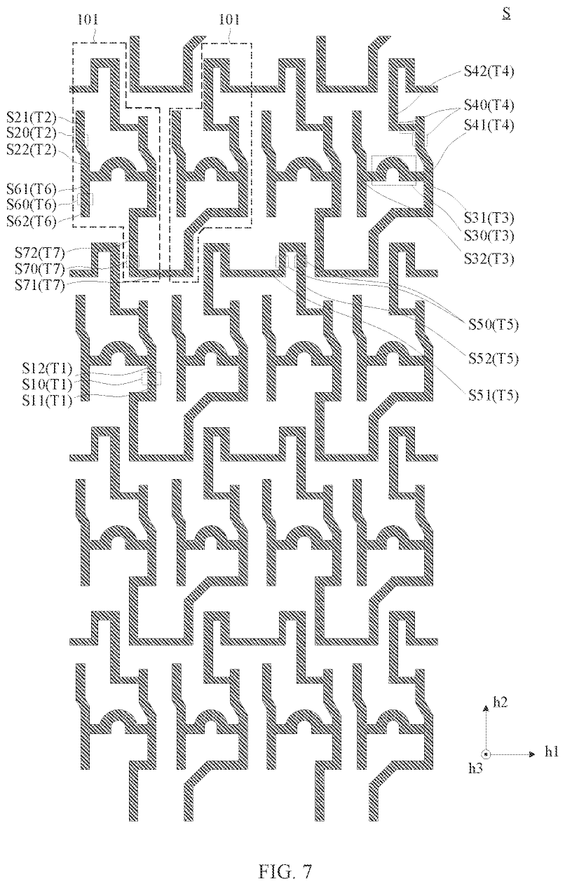

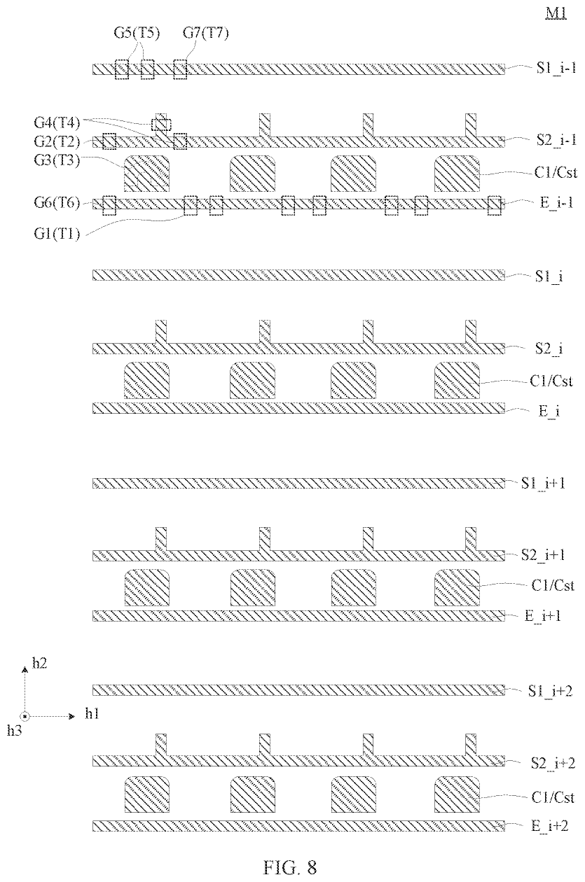

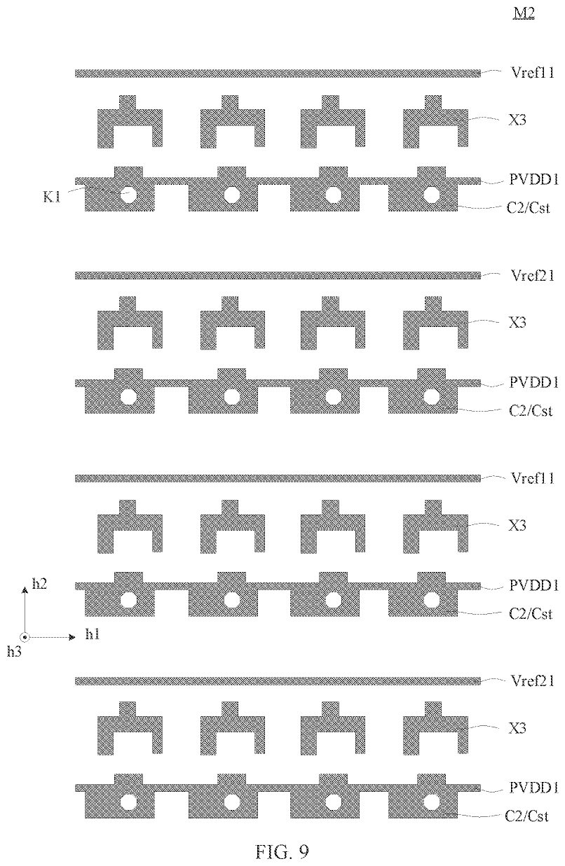

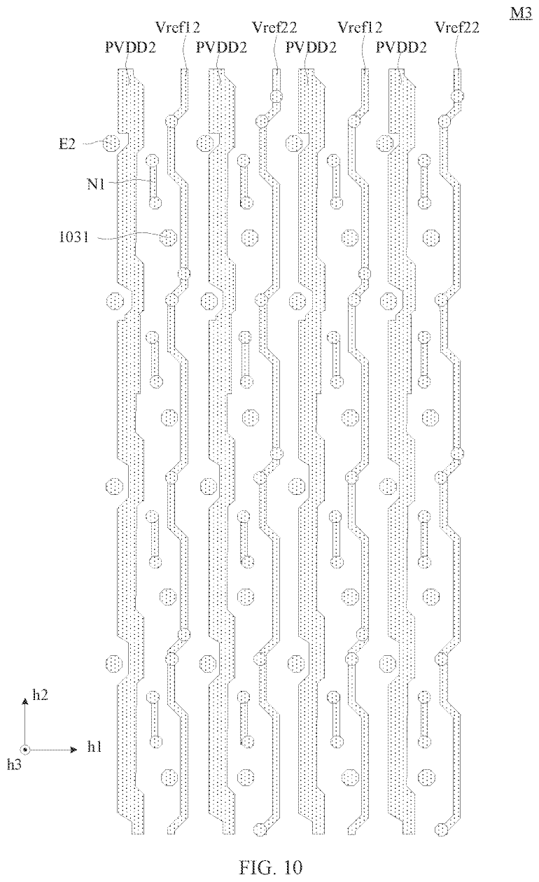

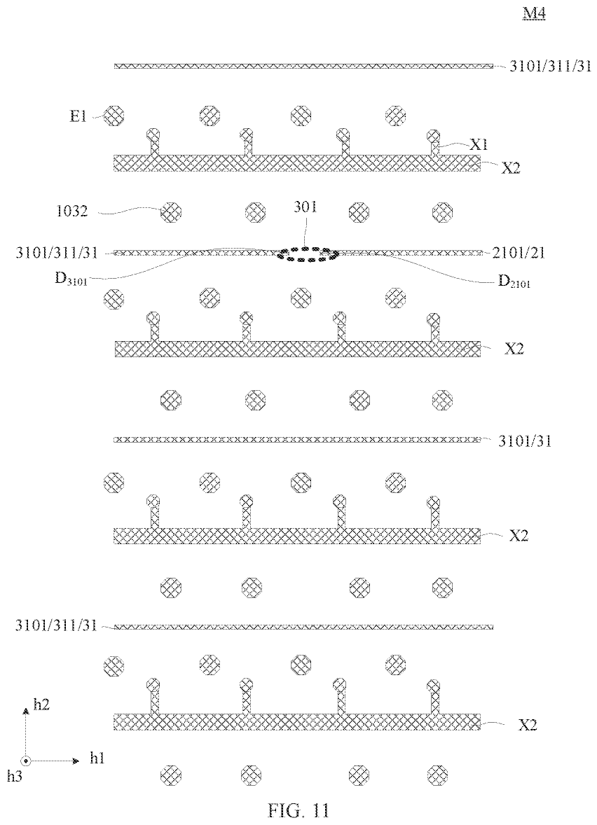

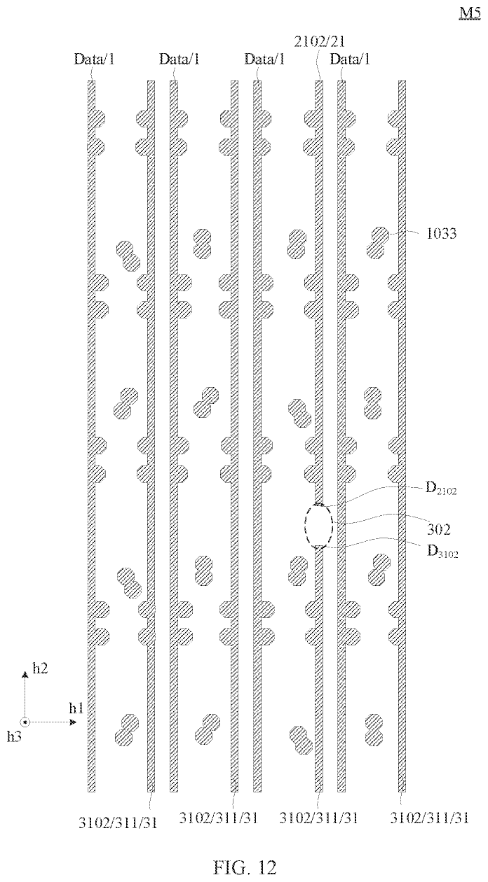

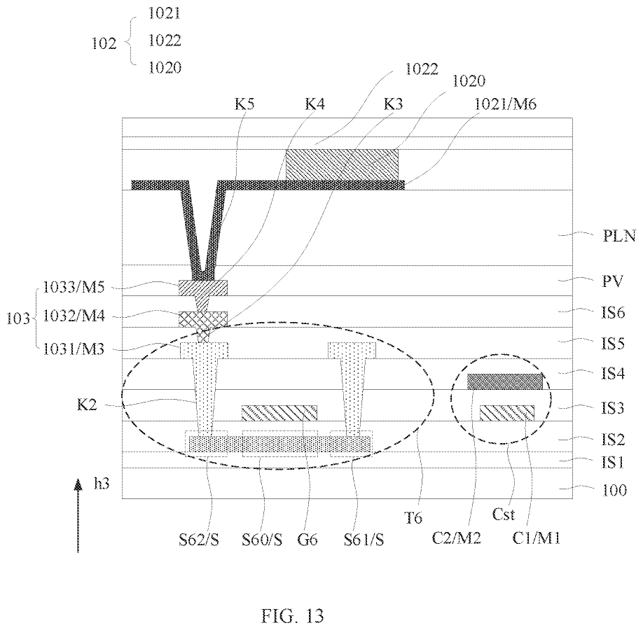

Referring to FIG. 6, FIG. 7, FIG. 8, FIG. 9, FIG. 9, FIG. 10, FIG. 11, FIG. 12 and FIG. 13, wiring in the display area AA will be illustrated. FIG. 7 is a top view of a semiconductor layer shown in FIG. 6 according to an embodiment of the present disclosure, FIG. 8 is a top view of a first metal layer shown in FIG. 6 according to an embodiment of the present disclosure, FIG. 9 is a top view of a second metal layer shown in FIG. 6 according to an embodiment of the present disclosure, FIG. 10 is a top view of a third metal layer shown in FIG. 6 according to an embodiment of the present disclosure, FIG. 11 is a top view of a fourth metal layer shown in FIG. 6 according to an embodiment of the present disclosure, FIG. 12 is a top view of a fifth metal layer shown in FIG. 6 according to an embodiment of the present disclosure, and FIG. 13 is a sectional view of a display area of a display panel according to an embodiment of the present disclosure. In FIG. 6, each pixel driving circuit 101 can have the circuit connecting relationship shown in FIG. 3.

As shown in FIG. 13, a display panel includes a substrate 100, and a first insulation layer IS1, a semiconductor layer S, a second insulation layer IS2, a first metal layer M1, a third insulation layer IS3, a second metal layer M2, a fourth insulation layer IS4, a third metal layer M3, a fifth insulation layer IS5, a fourth metal layer M4, a sixth insulation layer IS6 and a fifth metal layer M5 that are sequentially laminated at a side of the substrate 100.

Exemplarily, as shown in FIG. 7, the semiconductor layer S includes a first channel area S10 disposed by corresponding the pixel driving circuit 101; a first doping area S11 and a second doping area S12 that are located at two sides of the first channel area S10; a second channel area S20; a third doping area S21 and a fourth doping area S22 that are located at two sides of the second channel area S20; a third channel area S30; a fifth doping area S31 and a sixth doping area S32 that are located at two sides of the third channel area S30; a fourth channel area S40; a seventh doping area S41 and a eighth doping area S42 that are located at two sides of the fourth channel area S40; a fifth channel area S50; a ninth doping area S51 and a tenth doping area S52 that are located at two sides of the fifth channel area S50; a sixth channel area S60; an eleventh doping area S61 and a twelfth doping area S62 that are located at two sides of the sixth channel area S60; a seventh channel area S70; a thirteenth doping area S71 and a fourteenth doping area S72 that are located at two sides of the seventh channel area S70. One of two doping areas located at two sides of each channel area is a source area and the other is a drain area. The source area and the drain area are doped with impurities. Impurities include P-type impurities or N-type impurities. Exemplarily, the semiconductor layer S include any one or more of low-temperature polycrystalline silicon, amorphous silicon, and oxide semiconductor layers.

As shown in FIG. 6 and FIG. 8, the first metal layer M1 includes the first scan line S1, the second scan line S2, the light-emitting control signal line E and the first electrode plate C1 of the storage capacitor Cst described above.

As shown in FIG. 6, FIG. 7 and FIG. 8, along the direction h3 perpendicular to the plane of the display panel, the light-emitting control signal line E overlaps with the first channel area S10 and the sixth channel area S60 respectively. The overlapping portion between the light-emitting control signal line E and the first channel area S10, and the overlapping portion between the light-emitting control signal line E and the sixth channel area S60 can respectively form a gate G1 of the first transistor T1 and a gate G6 of the sixth transistor T6 in the same pixel driving circuit 101. The second scan line S2 overlaps with the second channel area S20 and the fourth channel area S40 as described above, respectively. Moreover, the overlapping portion between the second scan line S2 and the second channel area S20, and the overlapping portion between the second scan line S2 and the fourth channel area S40 can respectively form a gate G2 of the second transistor T2 and a gate G4 of the fourth transistor T4 in the same pixel driving circuit 101. The first scan line S1 overlaps with the fifth channel area S50 and the seventh channel area S70 as described above, respectively. Moreover, the overlapping portion between the first scan line S1 and the fifth channel area S50, and the overlapping portion between the first scan line S1 and the seventh channel area S70 can respectively form a gate G5 of the fifth transistor T5 and a gate G7 of the seventh transistor T7. Exemplarily, in the embodiments of the present disclosure, the second scan line S2_i and the first scan line S1_i+1 can be connected to the same scan driver unit, that is, the signals of the second scan line S2_i and the first scan line S1_i+1 can be the same. The fifth transistor T5 and seventh transistor T7 as described above can respectively belong to two pixel driving circuits 101 which are disposed adjacent to each other on the second direction h2. Moreover, according to the scanning order of the display panel, a previous pixel driving circuit 101 includes the seventh transistor T7 described above, while a latter pixel driving circuit 101 includes the fifth transistor T5 described above. Taking the first scan line S1_i+1 shown in FIG. 8 as an example, the overlapping portion between the first scan line S1_i+1 and the fifth channel area S50 forms a gate G5 of the fifth transistor T5 of the (i+1)^{th} pixel driving circuit. The overlapping portion between the first scan line S1_i+1 and the seventh channel area S70 forms a gate G7 of the seventh transistor T7 of the i^{th} pixel driving circuit.

The first electrode plate C1 of the storage capacitor Cst overlaps with the third channel area S30 described above, and the overlapping portion between the first electrode plate C1 of the storage capacitor Cst and the third channel area S30 to form a gate G3 of the third transistor T3.

Exemplarily, as shown in FIG. 6 and FIG. 8, the fourth transistor T4 and the fifth transistor T5 can form a dual-gate transistor with two gates to reduce the leakage current of the first node N1, improving the potential stability of the first electrode N1.

As shown in FIG. 6 and FIG. 9, the second metal layer M2 includes a second electrode plate C2 of the storage capacitor Cst, a first reference voltage signal sub-line Vref11, a second reference voltage signal sub-line Vref21, and a first supply voltage sub-line PVDD1. The first reference voltage signal sub-line Vref11 is configured to transmit the first reference voltage, and the second reference voltage signal sub-line Vref21 is configured to transmit the second reference voltage. The first supply voltage sub-line PVDD1 is configured to transmit the first supply voltage.

Exemplarily, as shown in FIG. 6 and FIG. 9, the first reference voltage signal sub-line Vref11, the second reference voltage signal sub-line Vref21 and the first supply voltage sub-line PVDD1 each extend along the first direction h1. The first reference voltage signal sub-line Vref11 and the second reference voltage signal sub-line Vref21 are alternately arranged in the second direction h2.

As shown in FIG. 6 and FIG. 10, the third metal layer M3 includes a third reference voltage signal sub-line Vref12, a fourth reference voltage signal sub-line Vref22 and a second supply voltage sub-line PVDD2.

As shown in FIG. 6, FIG. 9 and FIG. 10, the third reference voltage signal sub-line Vref12 intersects with an extension direction of the first reference voltage signal sub-line Vref11. The fourth reference voltage signal sub-line Vref22 intersects with the extension direction of the second reference voltage signal sub-line Vref21. The second supply voltage sub-line PVDD2 intersects with the extension direction of the first supply voltage sub-line PVDD1 described above. FIG. 10 schematically shows that the third reference voltage signal sub-line Vref12, the fourth reference voltage signal sub-line Vref22 and the second supply voltage sub-line PVDD2 each extend along the second direction h2. The third reference voltage signal sub-line Vref12 and the fourth reference voltage signal sub-line Vref22 are arranged alternately in the first direction h1.

The third reference voltage signal sub-line Vref12 is configured to transmit the first reference voltage, exemplarily, the third reference voltage signal sub-line Vref12 is electrically connected to the first reference voltage signal sub-line Vref11, so that the first reference voltage can be formed into a grid through the transmission path of the first reference voltage signal sub-line Vref11 and the third reference voltage signal sub-line Vref12 in the display area AA to reduce the voltage drop of the first reference voltage.

The fourth reference voltage signal sub-line Vref22 is configured to transmit the second reference voltage. Exemplarily, the fourth reference voltage signal sub-line Vref22 is electrically connected to the second reference voltage signal sub-line Vref21 described above, so that the second reference voltage can be formed into a grid through the transmission path of the second reference voltage signal sub-line Vref21 and the fourth reference voltage signal sub-line Vref22 in the display area AA to reduce the voltage drop of the second reference voltage.

The second supply voltage sub-line PVDD2 is configured to transmit the first supply voltage. Exemplarily, the second supply voltage sub-line PVDD2 is electrically connected to the first supply voltage sub-line PVDD1 described above, so that the first supply voltage can be formed into a grid through the transmission path of the first supply voltage sub-line PVDD1 and the second supply voltage sub-line PVDD2 in the display area AA to reduce the voltage drop of the first supply voltage.

As shown in FIG. 10, the third metal layer M3 further includes a first node N1. Combined with FIG. 7, one end of the first node N1 is electrically connected to an eighth doping area S42 and a tenth doping area S52 in the semiconductor layer S. As shown in FIG. 9, the second electrode plate C2 of the storage capacitor Cst includes a first through hole K1. The other end of the first node N1 is electrically connected to the first electrode plate C1 of the storage capacitor Cst, i.e., a gate G3 of the third transistor T, through the first through hole K1 and a though hole that penetrates the fourth insulation layer IS4 and the third insulation layer IS3.

As shown in FIG. 6 and FIG. 11, the fourth metal layer M4 includes a first shielding layer X1. As shown in FIG. 10, along a direction h3 perpendicular to the plane of the display panel, the first shielding layer X1 at least partially overlaps with the first node N1 described above, and the first shielding layer X1 is configured to shield the interference of other signals on the first node N1, to improve the potential stability of the first node N1. Exemplarily, the first shielding layer X1 is configured to receive a constant signal. Optionally, the constant signal includes any of the first supply voltage, second supply voltage, and reference voltage described above.

For example, as shown in FIG. 6 and FIG. 11, the fourth metal layer M4 further include a shielding connecting portion X2, the shielding connecting portion X2 is configured to electrically connect multiple first shielding layers X1 arranged along the first direction h1, and the shielding connecting portion X2 is electrically connected to the first shielding layer X1.

As shown in FIG. 6 and FIG. 12, the fifth metal layer M5 includes a data line Data.

Exemplarily, as shown in FIG. 11, the fourth metal layer M4 further includes a first data connecting electrode E1. As shown in FIG. 10, the third metal layer M3 further includes a second data connecting electrode E2. The data line Data is electrically connected to a third doping area S21 in the semiconductor layer S through the first data connecting electrode E1 and the second data connecting electrode E2.

Exemplarily, as shown in FIG. 9, the second metal layer M2 further includes a second shielding layer X3, and the second shielding layer X3 at least partially surrounds the first node N1, to further improve the potential stability of the first node N1. Exemplarily, the second shielding layer X3 is configured to receive a constant signal. Optionally, the constant signal includes any of the first supply voltage, the second supply voltage, and the reference voltage described above.

Exemplarily, combined with FIG. 13, the display panel further includes a connecting electrode 103. The pixel driving circuit 101 is electrically connected to the light-emitting element 102 through the connecting electrode 103. The connecting electrode 103 includes a first connecting sub-electrode 1031, a second connecting sub-electrode 1032 and a third connecting sub-electrode 1033. As shown in FIG. 10 and FIG. 13, the first connecting sub-electrode 1031 is located at the third metal layer M3. The first connecting sub-electrode 1031 is electrically connected to a twelfth doping area S62 of the sixth transistor T6 by the second through hole K2 which penetrates through the fourth insulation layer IS4, the third insulation layer IS3 and the second insulation layer IS2. As shown in FIG. 11 and FIG. 13, the second connecting sub-electrode 1032 is located at the fourth metal layer M4. The second connecting sub-electrode 1032 is electrically connected to the first connecting sub-electrode 1031 through the third through hole K3 which penetrates through the fifth insulation layer IS5. As shown in FIG. 12 and FIG. 13, the third connecting sub-electrode 1033 is located at the fifth metal layer M5. The third connecting sub-electrode 1033 is electrically connected to the second connecting sub-electrode 1032 through the fourth through hole K4 which penetrates through the sixth insulation layer IS6.

As shown in FIG. 13, the display panel further includes a passivation layer PV and a planarization layer PLN. The passivation layer PV is located at a side of the fifth metal layer M5 away from the substrate 100. The planarization layer PLN is located at a side of the passivation layer PV away from the fifth metal layer M5. The light-emitting element 102 includes a first electrode 1021, a light-emitting layer 1020 and a second electrode 1022. The first electrode 1021 is located in the sixth metal layer M6, and the sixth metal layer M6 is located at a side of the planarization layer PLN away from the passivation layer PV. The first electrode 1021 is electrically connected to the third connecting sub-electrode 1033 through the fifth through hole K5 which penetrates through the planarization layer PLN and the passivation layer PV.

Exemplarily, combined with FIG. 3, FIG. 5, and FIG. 6, the type-I common line 31 includes a first common sub-line 3101 and/or a second common sub-line 3102. The extension directions of the first common sub-line 3101 and the second common sub-line 3102 are intersected and are electrically connected with each other.

When the first connecting sub-line 2101, the second connecting sub-line 2102, the first common sub-line 3101 and the second common sub-line 3102 are disposed, exemplarily, in some embodiments of the present disclosure, the first connecting sub-line 2101 and the first common sub-line 3101 are parallel to each other and are disposed in a same layer, and/or, the second connecting sub-line 2102 and the second connecting sub-line 3102 are parallel to each other and are disposed in a same layer. Such configuration can simplify the manufacturing process of the display panel and reduce the thickness of the display panel. FIG. 2 schematically shows that the first connecting sub-line 2101 and the first common connecting sub-line 3101 extend along the first direction h1, and the second connecting sub-line 2102 and the second common connecting sub-line 3102 extend along the second direction h2.

Optionally, as shown in FIG. 6, along the direction h3 perpendicular to the plane of the display panel, in the embodiments of the present disclosure, the first connecting sub-line 2101 can at least partially overlap with the first reference voltage signal sub-line Vref11 or the second reference voltage signal sub-line Vref21; the first common sub-line 3101 can at least partially overlap with the first reference voltage signal sub-line Vref11 or the second reference voltage signal sub-line Vref21, and/or the second connecting sub-line 2102 can at least partially overlap with the third reference voltage signal sub-line Vref12 or the fourth reference voltage signal sub-line Vref22; the second common sub-line 3102 can at least partially overlap with the third reference voltage signal line Vref12 or the fourth reference voltage signal line Vref22 described above. The signals transmitted by the first reference voltage signal sub-line Vref11, the second reference voltage signal sub-line Vref21, the third reference voltage signal sub-line Vref12 and the fourth reference voltage signal sub-line Vref22 are constant signals, the first connecting sub-line 2101 can at least partially overlap with the first reference voltage signal sub-line Vref11 or second reference voltage signal sub-line Vref21 described above, and the second connecting sub-line 2102 can at least partially overlap with the third reference voltage signal line Vref12 or fourth reference voltage signal line Vref22 described above, so that the interference of the signals transmitted by the first connecting sub-line 2101 and the second connecting sub-line 2102 can be reduced while ensuring the light transmission area in the display area AA, which is conducive to improving the accuracy of the signals transmitted by the first connecting sub-line 2101 and the second connecting sub-line 2102. In addition, the first common sub-line 3101 can at least partially overlap with the first reference voltage signal sub-line Vref11 or the second reference voltage signal sub-line Vref21 described above, and/or, the second common sub-line 3102 can at least partially overlap with the third reference voltage signal line Vref12 or fourth reference voltage signal line Vref22 described above, so that it can ensure the same environment around the first common sub-line 3101 and the first common connecting line 2101, and/or the same environment around the second common sub-line 3102 and the second connecting sub-line 2102.

FIG. 6 schematically shows that one part of the first connecting sub-line 2101 overlaps with the first reference voltage signal sub-line Vref11, and the other part of the first connecting sub-line 2101 overlaps with the second reference voltage signal sub-line Vref12; one part of the first common sub-line 3101 overlaps with the first reference voltage signal sub-line Vref11, the other part of the first common sub-line 3101 overlaps with the second reference voltage signal sub-line Vref12; one part of the second connecting sub-line 2102 overlaps with a third reference voltage signal sub-line Vref12, and the other part of the second connecting sub-line 2102 overlaps with the fourth reference voltage signal sub-line Vref22; one part of the second common sub-line 3102 overlaps with the third reference voltage signal sub-line Vref12, and the other part of the second common sub-line 3102 overlaps with the fourth reference voltage signal sub-line Vref22.

Optionally, in the embodiments of the present disclosure, the first connecting sub-line 2101 and/or the first common sub-line 3101 can be disposed in a same layer as any one of the first scan line S1, the second scan line S2, the light-emitting control signal line E, the first reference voltage signal sub-line Vref11, the second reference voltage signal sub-line Vref21, and the first shielding layer X1 described above. The second connecting sub-line 2102 and/or the second common sub-line 3102 can be disposed in a same layer as any of the second supply voltage sub-line PVDD2, the third reference voltage signal sub-line Vref12, the fourth reference voltage signal sub-line Vref22, and the data line Data described above. In this way, there is no need to add a new layer in the display panel to dispose the first connecting sub-line 2101, the first common sub-line 3101, the second connecting sub-line 2102 and the second common sub-line 3102, which is conducive to simplifying the manufacturing process of the display panel and reducing the thickness of the display panel. FIG. 6 and FIG. 11 schematically shows that the first connecting sub-line 2101 and the first common connecting sub-line 3101 are located at the fourth metal layer M4, that is, the first connecting sub-line 2101 and/or the first common connecting sub-line 3101 are located at a same layer as the first shielding layer X1 described above. FIG. and FIG. 12 schematically shows that the second connecting sub-line 2102 and the second common connecting sub-line 3102 are located at the fifth metal layer M5, that is, the second connecting sub-line 2102 and/or the second common connecting sub-line 3102 are located at a same layer as the data line Data described above.

Exemplarily, combined with FIG. 3 and FIG. 5, part of the type-I common line 31 includes the first common line 311. The first common line 311 is insulated and crossed with the edge connecting line 210_S. The display area AA includes the first pixel driving circuit of 1011 and the second pixel driving circuit 1012 that are arranged along the extension direction of the first common line 311. The first pixel driving circuit 1011 and the second pixel driving circuit 1012 that are adjacent to each other. The first common line 311 overlaps with the first pixel driving circuit 1011. A part of the type-I connecting line 21 parallel to the first common line 311 overlaps with the second pixel driving circuit 1012.

Exemplarily, the first common line 311 includes the first common sub-line 3101 extending along the first direction h1 and/or the second common sub-line 3102 extending along the second direction h2. FIG. 3 schematically shows that the first common line 311 includes the first common sub-line 3101 extending along the first direction h1 and the second common sub-line 3102 extending along the second direction h2.

As shown in FIG. 3, the first common sub-line 3101 in the first common line 311 can cross with the third edge connecting line 210_S3 and/or the fourth edge connecting line 210_S4. For the first common sub-line 3101 that crosses the third edge connecting line 210_S3, the first pixel driving circuit 1011 and second pixel driving circuit 1012 corresponded are arranged along the first direction h1.

Combined with FIG. 5 and FIG. 11, an end D₃₁₀₁ of the first common sub-line 3101 and an end D₂₁₀₁ of the first common sub-line 2101 in the type-I connecting line 21 are spaced with a first gap 301.

As shown in FIG. 3, the second common sub-line 3102 in the first common line 311 can be crossed with the first edge connecting line 210_S1 and/or the second edge connecting line 210_S2. For the second common sub-line 3102 that crosses the second edge connecting line 210_S2, the first pixel driving circuit 1011 and the second pixel driving circuit 1012 corresponded are arranged along the second direction h2.

Combined with FIG. 5 and FIG. 12, an end D₃₁₀₂ of the second common sub-line 3102 and an end D₂₁₀₂ of the second common sub-line 2102 in the type-I connecting line 21 are spaced with a second gap 302.

It should be noted that that the first gap 301 as shown in FIG. 5 is located between the first pixel driving circuit 1011 and the second pixel driving circuit 1012, and the overlapping configuration between the second gap 302 and the second pixel driving circuit 1012 is only schematically shown. The embodiments of the present disclosure do not limit the relative position relationship among the first gap 301, the second gap 302 and the pixel driving circuit 101.

In the embodiments of the present disclosure, the first common line 311 which is insulated and crossed with the edge connecting line 210_S is disposed in the display panel, the first common line 311 overlaps with the first pixel driving circuit 1011, and part of the type-I connecting line 21 parallel to the first common line 311 overlaps with the second pixel driving circuit 1012, and the first pixel driving circuit 1011 and the second pixel driving circuit 1012 are disposed adjacent to each other along an extension direction of the first common line 311, which can make the first common line 311 extend from a side of the edge connecting line 210_S away from the light transmission area TA to a side adjacent to the light transmission area TA. Compared with the way of disconnecting the first common line 311 at the edge connecting line 210_S, on the one hand, it can increase the conducting path of the common voltage in the area of the edge connecting line 210_S adjacent to the light transmission area TA, which is conductive to further reducing the voltage drop of the common voltage in the area with a large distance from the drive chip, and improving the consistency of brightness at different positions in the display area AA. On the other hand, it can improve the space utilization rate at the position of the first pixel driving circuit 1011.

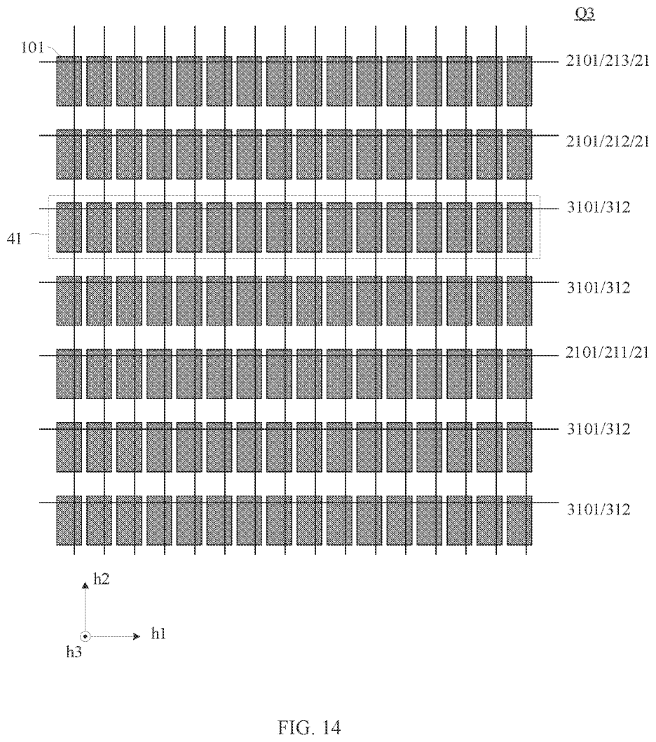

Exemplarily, as shown in FIG. 3, the type-I common line 31 includes the second common line 312. The second common line 312 is insulated and crossed with the edge connecting line 210_S. FIG. 14 is a simplified and enlarged diagram of an area Q3 shown in FIG. 3 according to an embodiment of the present disclosure. As shown in FIG. 14, the display area AA includes a first pixel driving circuit group 41. The first pixel driving circuit group 41 includes multiple pixel driving circuits 101 arranged along the extension direction of the second common line 312.

Along the direction h3 perpendicular to the plane of the display panel, multiple pixel driving circuits 101 in the first pixel driving circuit group 41 each overlap with the second common line 312, and each stagger with part of the type-I connecting line 21 parallel to the second common line 312, that is, multiple pixel driving circuits 101 in the first pixel driving circuit group 41 does not overlap with the part of the type-I connecting line 21 parallel to the second common line 312. As shown in FIG. 14, the extending line of the second common line 312 and the connecting sub-line of the type-I connecting line 21 parallel to the second common line 312 are staggered with each other.

Exemplarily, the second common line 312 includes a first common sub-line 3101 extending along the first direction h1 and/or a second common sub-line 3102 extending along the second direction h2. FIG. 3 schematically shows that the second common line 312 includes a first common sub-line 3101 extending along the first direction h1 and/or a second common sub-line 3102 extending along the second direction h2.

In the embodiments of the present disclosure, the second common line 312 and the edge connecting line 210_S are insulated and crossed, the second common line 312 overlaps with the first pixel driving circuit group 41, and the connecting sub-line of the type-I connecting line 21 parallel to the second common line 312 does not overlap with the first pixel driving circuit group 41, so that the length of the second common line 312 can be set as long as possible to increase the conducting path of the common voltage between the edge connecting line 210_S and the light transmission area TA, thereby while improving the display consistency in the display area AA, the short circuit risk of the second common line 312 and the connecting sub-line having a same extension direction as the second common line 312, which is conducive to reducing the wiring difficulty in the display area AA.

As shown in FIG. 3, the length of the second common line 312 is greater than the length of the first common line 311 which has the same extension direction as the second common line 312. The second common line 312 can be crossed and electrically connected to the first common line 311 which extends in a different direction from the second common line 312.

Exemplarily, as shown in FIG. 3, multiple type-I connecting lines 21 at least include a first connecting line 211, a second connecting line 212 and a third connecting line 213 that are adjacent to one another. A distance d12 between the connecting sub-line of the second connecting line 212 parallel to the extension direction of the second common line 312 and the connecting sub-line of the first connecting line 211 parallel to the extension direction of the second common line 312 is greater than or equal to a distance d23 between the connecting sub-line of the second connecting line 212 parallel to the extension direction of the second common line 312 and the connecting sub-line of the third connecting line 213 parallel to the extension direction of the second common line 312. In this way, at least a disposing space can be left for the second common line 312 between the connecting sub-line of the second connecting line 212 parallel to the extension direction of the second common line 312 and the connecting sub-line of the first connecting line 211 parallel to the extension direction of the second common line 312. The second common line 312 is located between the connecting sub-line of the second connecting line 212 parallel to the second common line 312 and the connecting sub-line of the first connecting line 211 parallel to the second common line 312.

Exemplarily, the number of the second common line 312 can be adjusted according to the distance d12 between the connecting sub-line of the second connecting line 212 parallel to the extension direction of the second common line 312 and the connecting sub-line of the first connecting line 211 parallel to the extension direction of the second common line 312. FIG. 3 schematically shows that two second common lines 312 are disposed between the first common line 211 and the second common line 212.

Exemplarily, in the embodiments of the present disclosure, a distance between the connecting sub-line of the first connecting line 211 parallel to the extension direction of the second common line 312 and the second common line 312 is greater than or equal to the distance between the second connecting line 212 and the connecting sub-line of the third connecting line 213 parallel to the extension direction of the second common line 312. And/or, a distance between the connecting sub-line of the second connecting line 212 parallel to the extension direction of the second common line 312 and the second common line 312 is greater than or equal to the distance between the second connecting line 212 and the connecting sub-line of the third connecting line 213 parallel to the extension direction of the second common line 312. In this way, while increasing the conducting path of the common voltage and reducing the drop of the common voltage, the distance between the second connecting line 212 and the connecting sub-line of the third connecting line 213 parallel to the extension direction of the second common line 312 can be set as small as possible, so that the length difference between the second connecting line 212 and the third connecting line 213 can be small, which is conducive to reducing the load difference between the second connecting line 212 and the third connecting line 213.

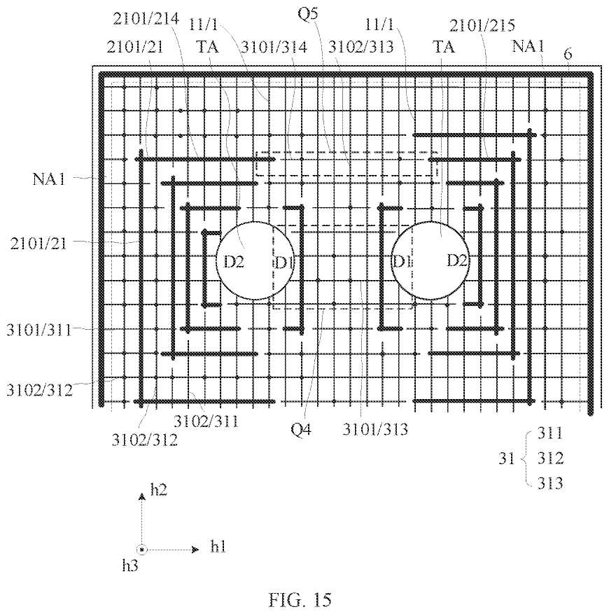

FIG. 15 is a partial enlarged schematic diagram of a display panel according to another embodiment of the present disclosure. Exemplarily, as shown in FIG. 15, the display panel includes at least two light transmission areas TA. Exemplarily, photosensitive devices can be subsequently disposed by corresponding to two light transmission areas TA. The type-I common line 31 includes the third common line 313. At least part of the third common line 313 is located between two adjacent light transmission areas TA.

Exemplarily, the third common line 313 includes a first common sub-line 3101 and/or a second common sub-line 3102. FIG. 15 schematically shows that the third common line 313 includes the first common sub-line 3101 and the second common sub-line 3102, and the first common sub-line 3101 is electrically connected with at least part of the second common sub-line 3102 that crosses with the first common sub-line 3101.

Disposing the third common line 313 can further increase the conducting path of the common voltage in the area between the edge connecting line 210_S and the light transmission area TA, further reduce the voltage drop of the common signal transmitted by the common line, and improve the display consistency at all positions in the display area AA.

As shown in FIG. 15, the extension line of the first common sub-line 3101 included by the third common line 313 passes through at least one light transmission area TA.

The second common sub-line 3102 included in the third common line 313 can be crossed and electrically connected to the first common sub-line 3101 in the first common line 311 and/or the first common sub-line 3101 in the second common line 312.

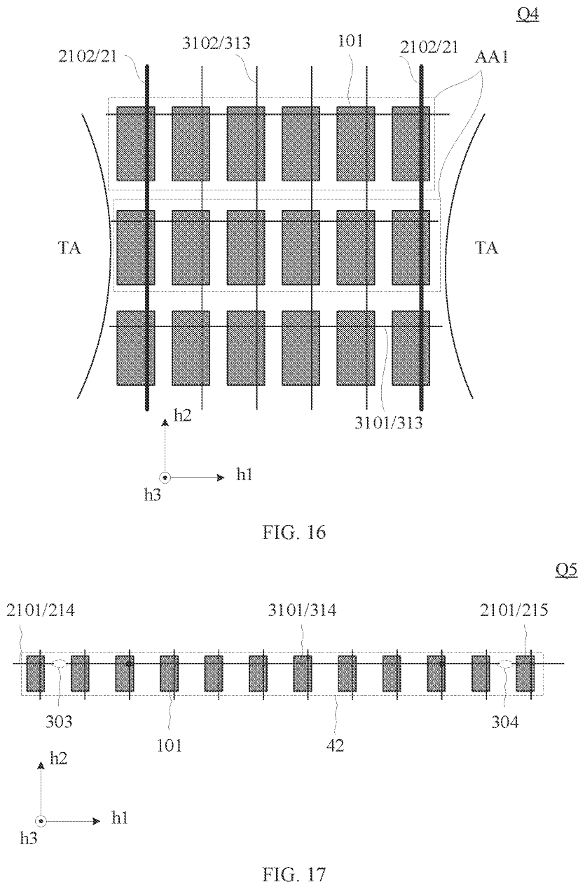

FIG. 16 is a simplified enlarged schematic diagram of an area Q4 shown in FIG. 15 according to an embodiment of the present disclosure. As shown in FIG. 15 and FIG. 16, at least one first display sub-area AA1 is included between two adjacent light transmission areas TA. The first display sub-area AA1 includes a pixel driving circuits 101 arranged along the arranging direction of two adjacent light transmission areas TA. The arranging direction of two adjacent light transmission areas TA includes the first direction h1 or the second direction h2. The first display sub-area AA1 further includes x connecting sub-lines arranged along the arranging direction TA of two adjacent light transmission areas TA and y third common lines 313 arranged along the arranging direction of two adjacent light transmission areas TA. The extension line of the third common line 313 is staggered with the light transmission areas TA.

As shown in FIG. 16, when two adjacent light transmission areas TA is arranged along the first direction h1, the first display sub-area AA1 includes a pixel driving circuits 101 arranged along the first direction h1, y second common sub-lines 3102 arranged along the first direction h1, and x second connecting sub-lines 2102 arranged along the first direction h1. Where, x+y≤a. That is, the total number of the type-I connecting line 21 or the third common line 313 between two light transmission areas TA does not exceed the number of the pixel driving circuit 101. Based on this configuration manner, the type-I connecting line 21 or the third common line 313 between two light transmission areas TA can overlap with the pixel driving circuit 101 in the first display sub-area AA1, which can avoid disposing the type-I connecting line 21 and the third common line 313 at the position where the pixel driving circuit 101 is not disposed in the first display sub-area AA1, so that it is conductive to improve the light transmittance in the first display sub-area AA1. Meanwhile, at most one third common line 313 and one connecting sub-line of the first connecting line 21 having an extension direction parallel to the third common line 313 can be disposed at any position of each pixel driving circuit 101 in the first display sub-area AA1, so as to avoid adding new layer in the display panel, which is conducive to thinning the display panel.

Exemplarily, as shown in FIG. 16, when multiple first display sub-areas AA1 are included between two adjacent light transmission areas TA, multiple first display sub-areas AA1 are arranged along the second direction h2, and the number of pixel driving circuit 101 in different first display sub-areas AA1 can be the same or different. FIG. 16 schematically shows that three first display sub-areas AA1 arranged along the second direction h2 between two adjacent light transmission areas TA. Each first display sub-area AA1 includes six pixel driving circuits, two second connecting sub-lines 2102 and four second common lines 3102, that is, a=6, x=2 and y=4.

Exemplarily, as shown in FIG. 15, the light transmission area TA adjacent to the first non-displaying area NA1 includes a first end D1 and a second end D2. The first end D1 is located at a side of one light transmission area TA adjacent to the other light transmission area TA, and the second end D2 is located at a side of the light transmission area TA adjacent to the first non-displaying area NA1. FIG. 15 schematically shows that the display panel includes two light transmission areas TA both of which are adjacent to the first non-display area NA1.

The signal line 1 includes the first signal line 11 passing through the light transmission area TA. The distance between the first signal line 11 and the first end D1 of the transmission area TA in which the first signal line 11 is passed through is smaller than the distance between the first signal line 11 and the second end D2. The part of the type-I connecting line 21 that is electrically connected to the first signal line 11 is located between the second end D2 and the first non-display area NA1. As shown in FIG. 15, the second connecting sub-line 2102 of the type-I connecting line 21, which is electrically connected to the first signal line 11, is located between the second end D2 and the first non-display area NA1.

In this way, the part of the type-I connecting line 21 that is electrically connected to the first signal line 11 is prevented from disposing between two adjacent light transmission areas TA, thus, a greater number of third common line 313 can be disposed between two adjacent light transmission areas TA, which is conducive to increasing the conducting path of the common voltage, reducing the voltage drop of the common voltage in the first display sub-area AA1, and improving the brightness consistency at different positions in the display area AA.

Exemplarily, as shown in FIG. 3 and FIG. 15, the type-I connecting line 21 at least further includes the fourth connecting line 214 and the fifth connecting line 215, the fourth connecting line 214 and the fifth connecting line 215 are electrically connected to different signal lines 1. Along the first direction h1, the second connecting sub-line 2102 of the fourth connecting line 214 and the second connecting sub-line 2102 of the fifth connecting 215, are located at two sides of the light transmission area TA.

As shown in FIG. 3 and FIG. 15, the type-I common line 31 further includes a fourth common line 314. The fourth common line 314 is located between the first connecting sub-line 2101 of the fourth connecting line 214 and the first connecting sub-line 2101 of the fifth connecting line 215. Disposing the fourth common line 314 can increase the conducting path of the common voltage and further reduce the voltage drop of the common voltage.

Exemplarily, as shown in FIG. 3, the signal line 1 connected to the fourth connecting line 214 can be disconnected with the signal line 1 connected to the fifth connecting line 215 by the same light transmission area TA. One light transmission area TA can be included between the second connecting line 2102 of the fourth connecting line 214 and the second connecting line 2102 of the fifth connecting line 215. Alternatively, as shown in FIG. 15, the signal line 1 connected to the fourth connecting line 214 and the signal line 1 connected to the fifth connecting line 215 can be disconnected by different light transmission areas TA, respectively. At least two light transmission areas TA can be included between the second connecting line 2102 of the fourth connecting line 214 and the second connecting line 2102 of the fifth connecting line 215. Exemplarily, as shown in FIG. 3 and FIG. 15, the signal line 1 electrically connected to the fourth connecting line 214 is not adjacent to the signal line 1 electrically connected to the fifth connecting line 215.

As shown in FIG. 3 and FIG. 15, the fourth common line 314 extends along the first direction h1. The connecting sub-line of the type-I connecting line 21 that extends in a different direction from the fourth common line 314 does not overlap with the fourth common line 314.

FIG. 17 is a simplified enlarged schematic diagram of area Q5 shown in FIG. 15 according to an embodiment of the present disclosure. As shown in FIG. 17, the display area AA further includes a second pixel driving circuit group 42. The second pixel driving circuit group 42 includes multiple pixel driving circuits 101 arranged along the extension direction of the fourth common line 314. In the embodiments of the present disclosure, part of the pixel driving circuits 101 overlaps with the first connecting sub-line 2101 of the fourth connecting line 214, another part of the pixel driving circuits 101 overlaps with the fourth common line 314, and another part of the pixel driving circuits 101 overlaps with the first connecting sub-line 2101 of the fifth connecting line 215. There is a third gap 303 between the first connecting sub-line 2101 of the fourth connecting line 214 and the fourth common line 314, and there is a fourth gap 304 between the first connecting sub-line 2101 of the fifth connecting line 215 and the fourth common line 314.

As shown in FIG. 3 and FIG. 15, the fourth common line 314 is crossed and electrically connected with part of the first common line 311. The fourth common line 314 staggers with the second common line 312 which extends along the second direction h2. As shown in FIG. 15, the fourth common line 314 is crossed and electrically connected with part of the third common line 313.

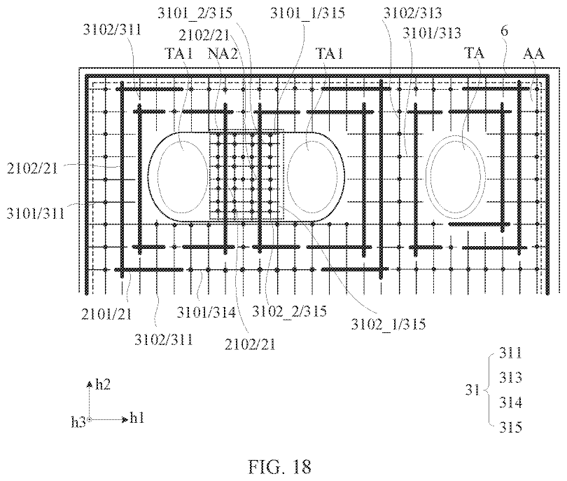

FIG. 18 is a partial enlarged schematic diagram of a display panel according to another embodiment of the present disclosure. Exemplarily, as shown in FIG. 18, the light transmission area TA includes at least two transmittance sub-areas TA1. Optionally, two transmittance sub-areas TA1 can be arranged along the first direction h1.

As shown in FIG. 18, the display panel includes a second non-display area NA2 between two adjacent transmittance sub-areas TA1. When a photosensitive device is subsequently disposed, part of the photosensitive devices can be disposed to at least partially overlap with the second non-display area NA2, so that the external ambient light can pass through the second non-display area NA2 and emit into the photosensitive devices disposed by corresponding to the second non-display area NA2.

Exemplarily, as shown in FIG. 18, the type-I common line 31 includes a fifth common line 315. At least part of the fifth common line 315 is located in the second non-display area NA2.

Exemplarily, the fifth common line 315 includes a first common sub-line 3101 extending along the first direction h1 and/or a second common sub-line 3102 extending along the second direction h2. FIG. 18 schematically shows that the fifth common line 315 includes the first common sub-line 3101 and the second common sub-line 3102. At least part of the first common sub-line 3101 is crossed and electrically connected with the second common sub-line 3102.

The fifth common line 315 can increase the conduction path of the common voltage around the light transmission area TA, reduce the voltage drop of the common voltage, and further improve the display consistency at different positions in the display area AA.

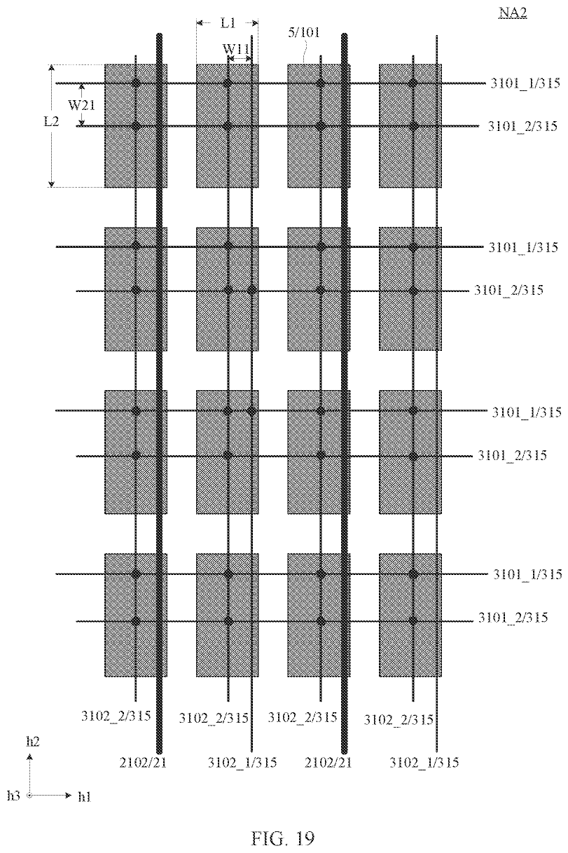

FIG. 19 is a simplified enlarged diagram of a second non-display area shown in FIG. 18 according to an embodiment of the present disclosure. Optionally, as shown in FIG. 19, the second non-display area NA2 includes a dummy pixel 5. The dummy pixel 5 is configured to not emit light. Optionally, the dummy pixel 5 includes a pixel driving circuit 101 and/or a light-emitting element.

When the dummy pixel 5 includes the pixel driving circuit 101, exemplarily, the structure of the pixel driving circuit 101 in the dummy pixel 5 is the same as that of sub-pixel pixel driving circuit 101 in the display area AA described above, that is, the pixel driving circuit 101 in the dummy pixel 5 further includes the first to seventh transistors and the storage capacitor as shown in FIG. 3. Each pixel driving circuit 101 can adopt the same wiring manner as the pixel driving circuit 101 in the display area AA. Disposing the pixel driving circuit 101 in the dummy pixel 5 can improve the uniformity of pattern density at different areas of the display panel.

As shown in FIG. 19, the dummy pixel 5 partially overlaps with the fifth common line 315 along the direction h3 perpendicular to the plane of the display panel. The pixel driving circuit 101 in the dummy pixel 5 partially overlaps with the fifth common line 315. In this way, while reducing the voltage drop of the common voltage, the space within the second non-display area NA2 can be reasonably utilized, so that disposing of the fifth common line 315 can be prevented from reducing the light transmittance in the second non-display area NA2, and more light from the external environment can emit into the photosensitive element through the second non-display area NA2.

For example, as shown in FIG. 5 and FIG. 19, a distance W11 between two adjacent second common sub-lines 3102 in the second non-display area NA2 is smaller than or equal to a distance W12 between two adjacent second common sub-lines 3102 in the display area AA. And/or, a distance W21 between two adjacent first common sub-lines 3101 in the second non-display area NA2 is smaller than or equal to a distance W22 between two adjacent first common sub-lines 3101 in the display area AA. FIG. 19 schematically shows that the distance W21 between two adjacent first common sub-lines 3101 in the second non-display area NA2 is smaller than a distance W22 between two adjacent first common sub-lines 3101 in the display area, and the distance W11 between two adjacent second common sub-lines 3102 in the second non-display area NA2 is smaller than the distance W12 between two adjacent second common sub-lines 3102 in the display area AA. In the second non-display area NA2, the first common sub-line 3101 is electrically connected to at least part of the second common sub-line 3102 crossing with the first common sub-line 3101.

In this way, the space of the second non-display area NA2 can be fully utilized to increase the densities of the first common sub-line 3101 and/or the second common sub-line 3102 of the fifth common line 315 in the second non-display area NA2, so that the conducting path of the common voltage can be further increased to further reduce the voltage drop of the common voltage, thereby improving the display consistency at all positions in the display area.

As shown in FIG. 19, in the second non-display area NA2, the distance W21 between two adjacent first common sub-lines 3101 is smaller than or equal to a height L2 of one pixel driving circuit 101 in the second direction h2. The distance W11 between two adjacent second common lines 3102 is smaller than or equal to a width L1 of one pixel driving circuit 101 in the first direction h1. Exemplarily, in the second non-display area NA2, in the embodiments of the present disclosure, two adjacent first common sub-lines 3101 can overlap at different positions of the same pixel driving circuit 101, and two adjacent second common sub-lines 3102 can overlap at different positions of the same pixel driving circuit 101, to increase the density of the common line in the second non-display area NA2.

As shown in FIG. 18, the extension line of one of two adjacent first common sub-lines 3101 in the fifth common line 315 can pass through part of the first common sub-line 3101 of the display area AA. In FIG. 18 and FIG. 19, this part of the first common sub-line of the second non-display area NA2 is marked as 3101_1. The extension line of the other of two adjacent first common sub-lines 3101 does not pass through the first common sub-line 3101 in the display area AA. In FIG. 18 and FIG. 19, this part of the first common sub-line of the second non-display area NA2 is marked as 3101_2.

Exemplarily, as shown in FIG. 18, part of the fifth common line 315 extends from display area AA to the second non-display area NA2. Taking the arrangement of two light transmission sub-areas TA1 along the first direction h1 as an example, as shown in FIG. 18, part of the second common sub-line 3102 in the fifth common line 315 extends from the display area AA to the second non-display area NA2. In FIG. 18 and FIG. 19, this part of the second common sub-line of the second non-display area NA2 is marked as 3102_1.

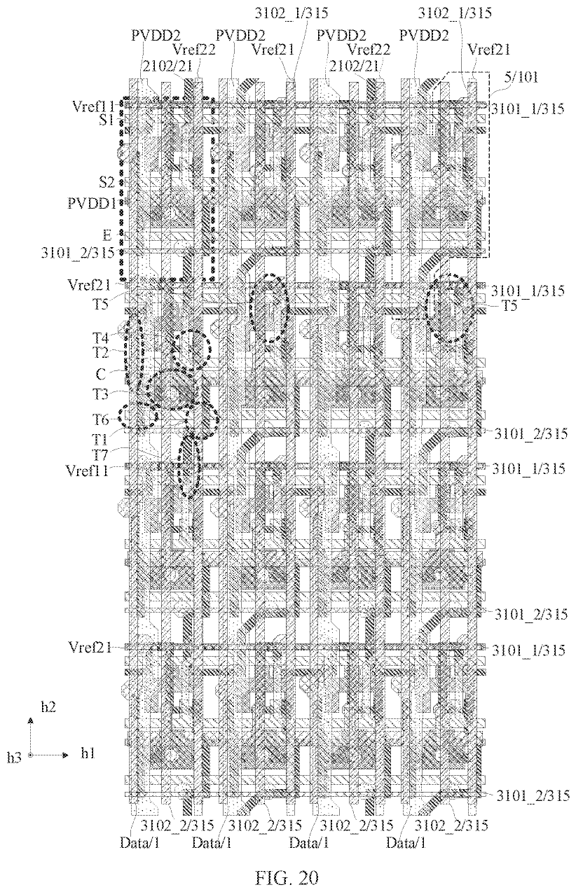

FIG. 20 is a wiring diagram corresponding to FIG. 19 according to an embodiment of the present disclosure. Exemplarily, as shown in FIG. 20, a second non-display area NA2 includes a first scan line S1, a second scan line S2, a light-emitting control signal line E, adata line, a first reference voltage signal sub-line Vref11, a second reference voltage signal sub-line Vref21, a third reference voltage signal sub-line Vref12, a fourth reference voltage signal sub-line Vref22, a first supply voltage sub-line PVDD1 and a second supply voltage sub-line PVDD2.

In some embodiments of the present disclosure, in the second non-display area NA2, the first common sub-line 3101_1 can overlap with the first reference voltage signal sub-line Vref11 or the second reference voltage signal sub-line Vref21; and/or, the second common sub-line 3102_1 can overlap the third reference voltage signal sub-line Vref12 or the fourth reference voltage signal sub-line Vref22 so that the wiring in the second non-display area NA2 has the same wiring environment as the wiring in the display area AA while improving the light transmittance of the second non-display area NA2. When manufacturing the display panel, the first common sub-line 3101_1 in the second non-display area NA2 and the first common sub-line 3101 in the display area AA described above can be formed by a same process. The second common sub-line 3102_1 in the second non-display area NA2 and the second common sub-line 3102 in the display area AA described above can be formed by a same process.

As shown in FIG. 18, another part of the second common sub-line 3102 in the fifth common line 315 terminates at the edge of the second non-display area NA2, that is, this part of the second common sub-line 3102 does not extend to the display area AA. In FIG. 18, FIG. 19, and FIG. 20, this part of the second common sub-line in the second non-display area NA2 is marked as 3102_2. Disposing the second common sub-line marked with 3102_2 can increase the conducting path of the common voltage in the second non-display area NA2.

Optionally, as shown in FIG. 6 and FIG. 20, the dummy pixel 5 does not include at least part of the connecting electrode 103 to disconnect the connecting between the light-emitting element in the second non-display area NA2 and the pixel driving circuit, so that the light-emitting element in the dummy pixel 5 does not emit light.

Optionally, in some embodiments of the present disclosure, at least one of the first common sub-line 3101_1, the first common sub-line 3101_2, the second common sub-line 3102_1 and the second common sub-line 3102_2 can be dispose at a same layer with at least part of the connecting electrode 103 in the display area AA, so as to avoid adding a new layer to the display panel, thereby reducing the thickness of the display panel.

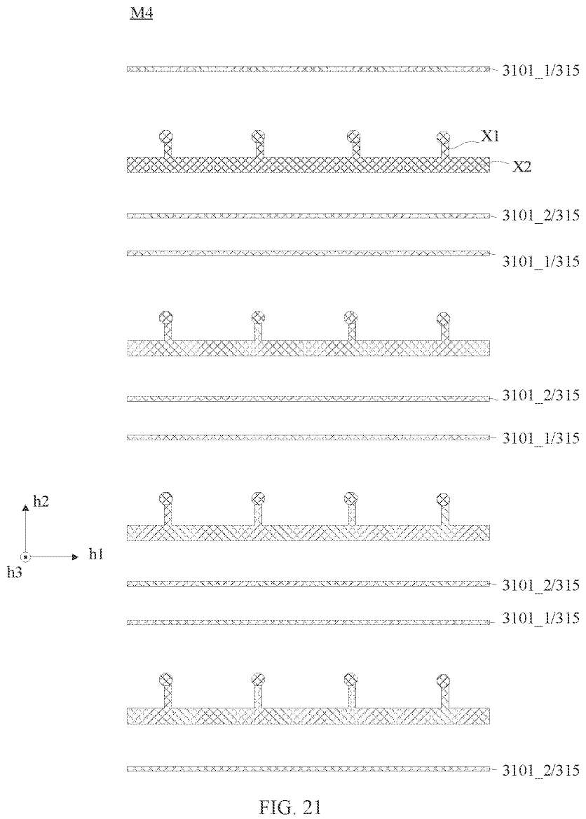

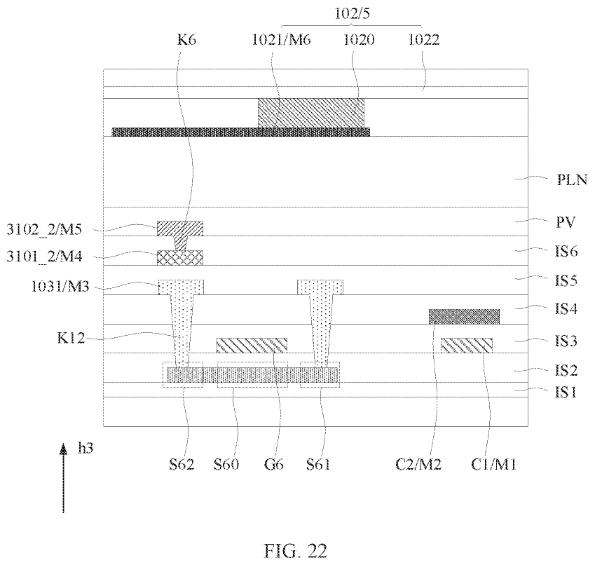

Exemplarily, in some embodiments of the present disclosure, the first common sub-line 3101_1 and the first common sub-line 3101_2 in the fifth common line 315 can be disposed at a same layer with the second connecting sub-electrode 1032 in the display area AA. Combined with FIG. 11, FIG. 20 and FIG. 21, FIG. 21 is a top view of the fourth metal layer shown in FIG. M4, in which the first common sub-line 3101_1 and the first common sub-line 3101_2 in the fifth common line 315 is disposed in a same layer (i.e., the fourth metal layer M4) as the second connecting sub-electrode 1032 in the display area AA. Combined with FIG. 13 and FIG. 22, FIG. 22 is a sectional view of a second non-display area of a display panel according to an embodiment of the present disclosure, in the second non-display area NA2, the fifth insulation layer IS5 does not include the through hole located between the first common sub-line 3101_2 and the first connecting sub-electrode 1031 described above.

Optionally, in some embodiments of the present disclosure, an extension line of the first common sub-line 3101_2 in the second non-display area NA2 can pass through multiple second connecting sub-electrodes 1032 arranged along the first direction h1 in the display area AA.

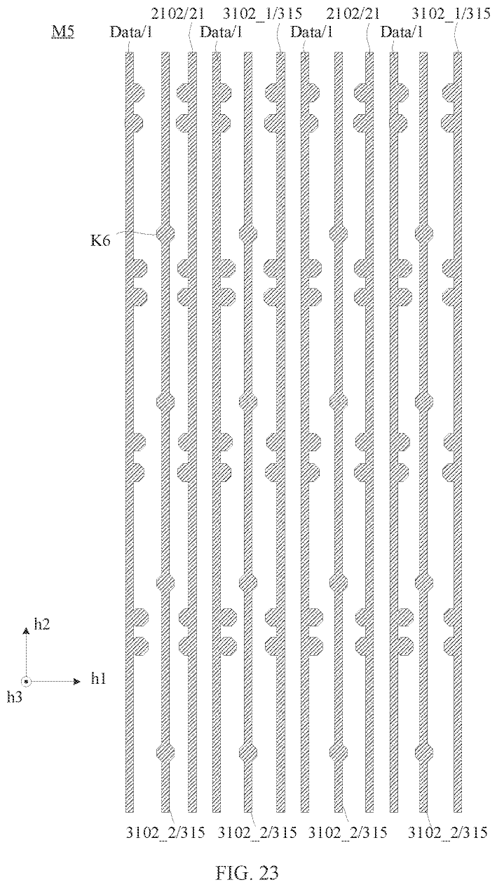

Exemplarily, in some embodiments of the present disclosure, the second common sub-line 3102_1 and the second common sub-line 3102_2 in the fifth common line 315 can be disposed at a same layer with the third connecting sub-electrode 1033 in the display area AA. Combined with FIG. 12, FIG. 20 and FIG. 23, FIG. 23 is a top view of the fifth metal layer M5 shown in FIG. 20, the second common sub-line 3102_1 and the second common sub-line 3102_2 in the fifth common line 315 can be disposed at a same layer (i.e., the fifth metal layer M5) with the third connecting electrode 1033 in display area AA. Exemplarily, combined with FIG. 20, FIG. 22, and FIG. 23, in some embodiments of the present disclosure, the second common sub-line 3102_2 can be electrically connected to the first common sub-line 3101_2 by the sixth through hole K6 penetrating the sixth insulation layer IS6 (not shown in FIG. 20 and FIG. 23). The sixth through hole K6 is formed in a same process as the fourth through hole K4.

Optionally, in some embodiments of the present disclosure, the extension line of the second common sub-line 3102_2 in the second non-display area NA2 can pass through multiple third connecting sub-electrode 1033 arranged along the second direction h2 in the display area AA.

As shown in FIG. 22, in the second non-display area NA2, the planarization layer PLN and the passivation layer PV do not include the through hole located between the second common sub-line 3102_2 and the first electrode 1021, to avoid the electrical connecting between the light-emitting element 102 in the dummy pixel 5 and the second common sub-line 3102_2.

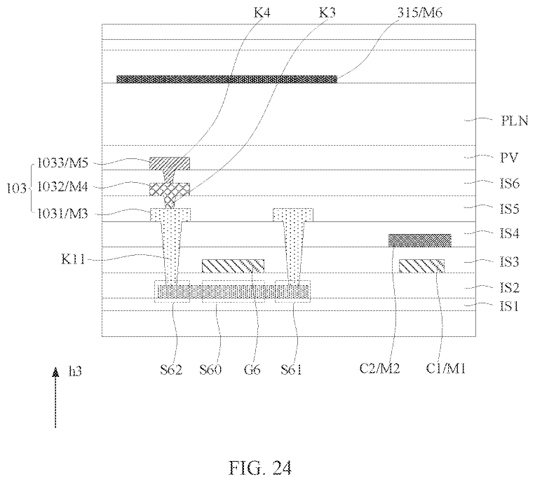

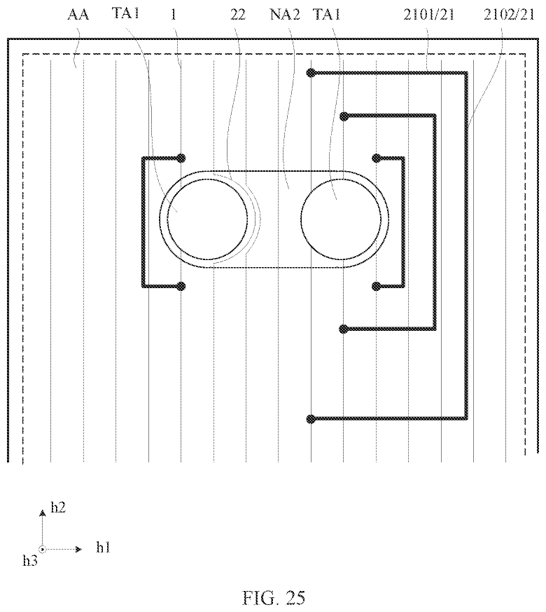

FIG. 24 is a sectional view of a second non-display area according to another embodiment of the present disclosure. Alternatively, as shown in FIG. 24, in some embodiments of the present disclosure, the dummy pixel 5 does not include the light-emitting element, at least part of the common line 315 is disposed in a same layer as the electrode of the light-emitting element in the display area AA. Optionally, combined with FIG. 13 and FIG. 24, in some embodiments of the present disclosure, the common line 315 is disposed in a same layer as the first electrode 1021 of the light-emitting element 102, that is, the common line 5 315 is disposed in a sixth metal layer M6, so as to avoid adding a new layer in the display panel, thereby reducing the thickness of the display panel.

FIG. 25 is a partial enlarged schematic diagram of a display panel according to another embodiment of the present disclosure. Exemplarily, as shown in FIG. 25, the connecting line further includes a type-II connecting line 22 located at a side of the second non-display area NA2 adjacent to the light transmission sub-area TA1. The type-II connecting line 22 partially surrounds the light transmission sub-area TA1. The type-II connecting line 22 can be connected to the signal line 1 disconnected by the light transmission sub-area TA1. It should be noted that that, for the sake of conciseness of the drawing, only the connecting line and signal lines are shown in FIG. 25, but other structures such as common lines and pixel driving circuits are not shown. In some embodiments of the present disclosure, by disposing the type-II connecting line 22 at a side of the second non-display area NA2 adjacent to the transmittance sub-area TA1, the number of the type-I connecting line 21 can be reduced in the display area AA, so that more space can be left for disposing common lines in the display area AA, which is conducive to increasing the number of common line in the display area AA, and reducing the voltage drop of the common voltage. Exemplarily, the type-II connecting line 22 can be located between the light transmission sub-area TA1 and the dummy pixel described above (not shown in FIG. 25).

Exemplarily, as shown in FIG. 1, FIG. 3 and FIG. 15, the first non-display area NA1 includes a common bus 6 electrically connected to multiple type-I common lines described above. Exemplarily, as shown in FIG. 1, the first non-display sub-area NA11, the second non-display sub-area NA12, the third non-display sub-area NA13 and the fourth non-display sub-area NA14 described above each include the common bus 6 described above. Optionally, the common bus 6 can be electrically connected to the bonding pad in the binding area BA, so that the common voltage transmitted by the drive chip is transmitted to the type-I common line 31 located in the display area AA through the common bus 6.

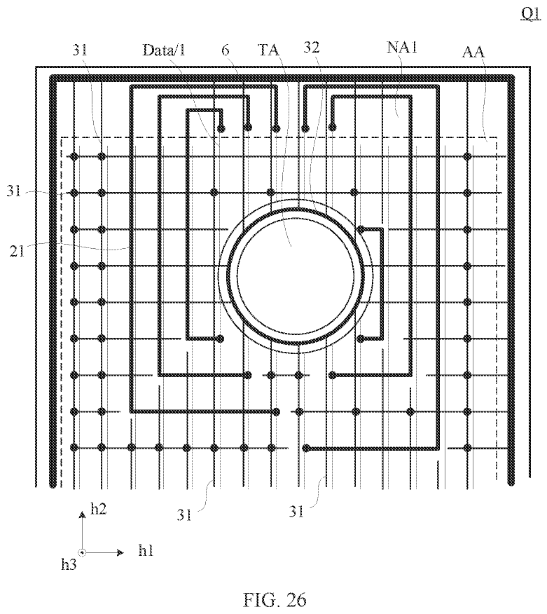

FIG. 26 is a partial enlarged schematic diagram of a display panel according to another embodiment of the present disclosure. Exemplarily, as shown in FIG. 26, part of the type-I connecting line 21 and part of the type-I common line 31 are both located in the first non-display area NA1, to reduce the space occupied by the type-I connecting line 21 and the type-I common line 31 in the display area AA, thereby reducing the wiring difficulty in the display area AA.

Exemplarily, as shown in FIG. 26, in the first non-display area NA1, the portion of the type-I common line 31 overlaps with the type-I connecting line 21 along the direction h3 perpendicular to the plane of the display panel, to improve the space utilization rate of the first non-display area NA1 and reduce the width of the first non-display area NA1.

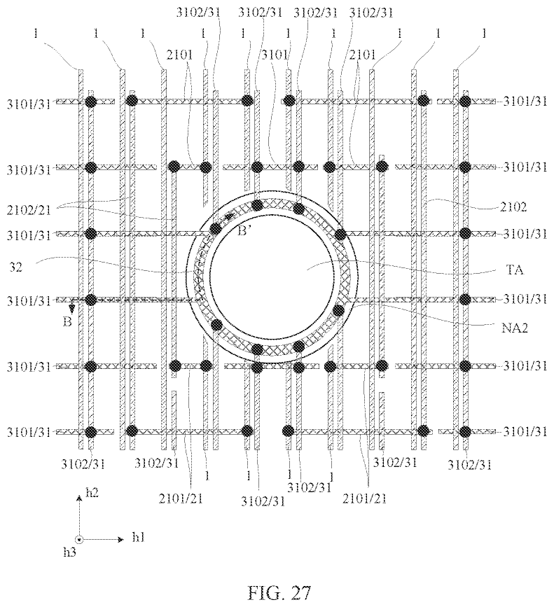

FIG. 27 is a partial enlarged schematic diagram of a display panel according to another embodiment of the present disclosure. Exemplarily, as shown in FIG. 26 and FIG. 27, the display panel further includes a type-II common line 32 located at a side of the light transmission area TA adjacent to the display area AA. The type-II common line 32 at least partially surrounds the light transmission area TA. The type-II common line 32 is located between the light transmission area TA and the display area AA, and the type-II common line 32 is electrically connected to the type-I common line 31. Disposing the type-II common line 32 can further increase the conducting path of the common voltage around the light transmission area TA and reduce the voltage drop of the common voltage. Moreover, the type-II common line 32 does not need to occupy the space of the display area AA, which is conducive to reducing the wiring difficulty of the display area AA.

Exemplarily, the type-II common line 32 and at least one of the type-I common lines 31 electrically connected to it are disposed in a same layer. The type-II common line 32 and at least one of the type-I common lines 31 electrically connected to it are contacted and electrically connected. Alternatively, along the direction h3 perpendicular to the plane of the display panel, an insulation layer is included between the type-II common line 32 and at least one of the type-I common lines 31. The insulation layer includes a through hole. The type-II common line 32 and at least one of the type-I common lines 31 are electrically connected through the through hole.

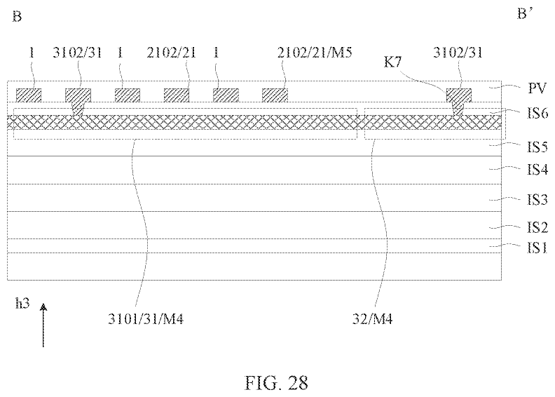

FIG. 28 is a sectional view along BB′ shown in FIG. 27 according to an embodiment of the present disclosure. Combined with FIG. 27 and FIG. 28, the type-I common line 31 includes the first common sub-line 3101 and the second common sub-line 3102. The first common sub-line 3101 extends along the first direction h1, and the second common sub-line 3102 extends along the second direction h2. FIG. 27 and FIG. 28 schematically shows that the signal line 1, the second common sub-line 3102 and the second common sub-line 2102 are disposed in a same layer (i.e., the fifth metal layer M5 described above), and the first common sub-line 3101, the first common sub-line 2101 and the second common line 32 are disposed in a same layer (i.e., the fourth metal layer M4 described above). The insulation layer between the type-II common line 32 and the type-I common line 31 includes the sixth insulation layer IS6 described above. The sixth insulation layer IS6 includes a seventh through hole K7 for connecting the type-II common line 32 and the second common sub-line 3102.

Optionally, as shown in FIG. 26 and FIG. 27, the shape of the orthographic projection of the type-II common line 32 on the plane of the display panel includes a circular ring.

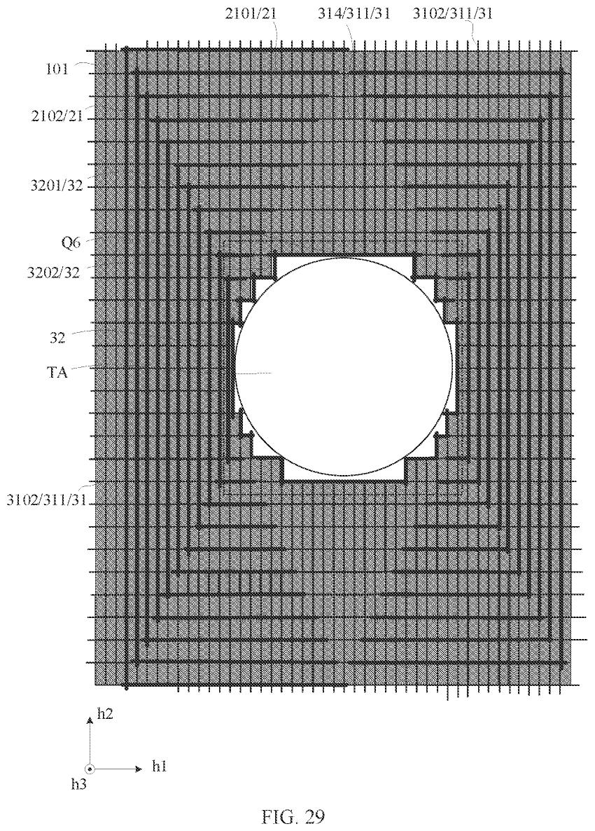

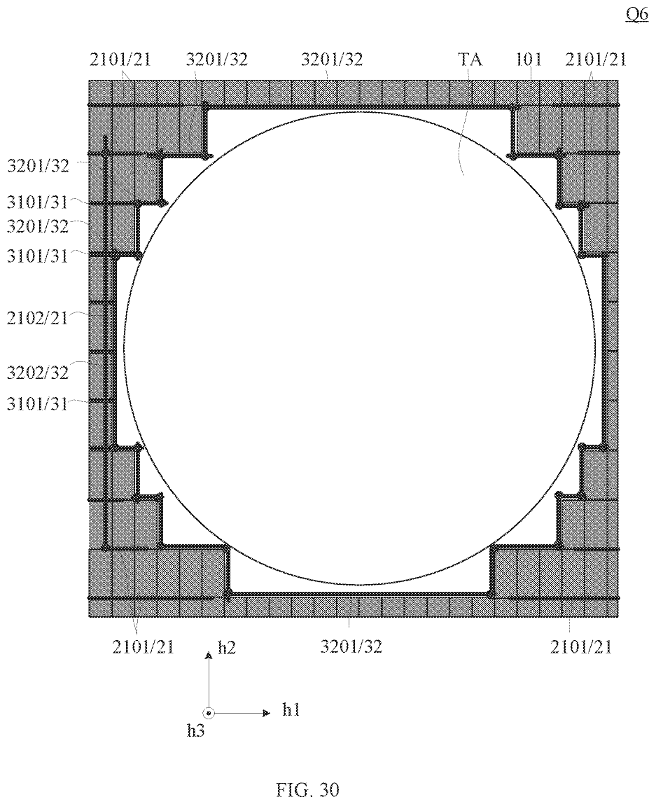

FIG. 29 is a schematic diagram of local enlargement of a display panel according to another embodiment of the present disclosure, and FIG. 30 is a simplified enlarged schematic diagram of an area Q6 shown in FIG. 29 according to an embodiment of the present disclosure. Alternatively, as shown in FIG. 29 and FIG. 30, the shape of the orthographic projection of the type-II common line 32 on the plane of the display panel includes a zigzag shape. Exemplarily, as shown in FIG. 30, the type-II common line 32 includes multiple first common sub-lines 3201 and multiple second common sub-lines 3202. The first common sub-line 3201 extends along the first direction h1, and the second common sub-line 3202 extends along the second direction h2. The first common sub-line 3201 and the second common sub-line 3202 are crossed and electrically connected to each other. The first common sub-line 3201 and the second common sub-line 3202 are both located between the display area AA and the light transmission area TA. As shown in FIG. 30, the first common sub-line 3201 and the second common sub-line 3202 that are adjacent to each other are electrically connected, and there is no gap between them. The first common sub-line 3201 and the second common sub-line 3202 that are adjacent to each other are spaced.

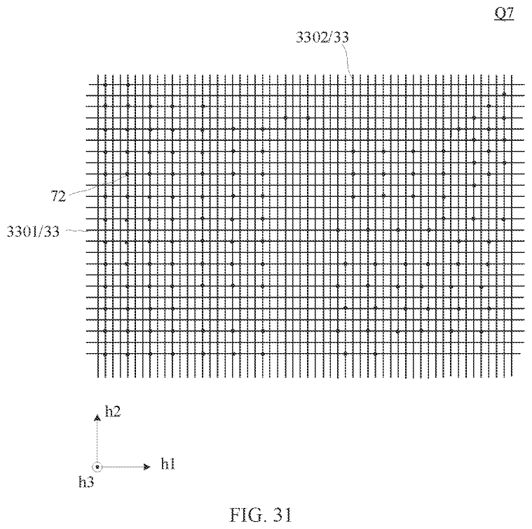

FIG. 31 is an enlarged schematic diagram of an area Q7 shown in FIG. 1 according to an embodiment of the present disclosure. Exemplarily, as shown in FIG. 31, the common line includes a type-III common line 33 located at a side of the edge connecting line away from the light transmission area TA. Disposing the third type common line 33 can further increase the conducting path of the common voltage in an area far away from the bonding pad area BA, which is conducive to improving the display consistency in different areas of display area AA. Moreover, in the embodiments of the present disclosure, the type-III common line 33 is located at a side of the edge connecting line away from the light transmission area TA, that is, the type-I connecting line 21 described above is not disposed at the position of the type-III common line 33, which can reduce the wiring difficulty of the type-III common line 33 and is conducive to improving the yield rate of the display panel.

Exemplarily, the type-III common line 33 includes a first common line 3301 extending along the first direction h1 and/or a second common line 3302 extending along the second direction h2. FIG. 31 schematically shows that the third common line 33 includes the first common line 3301 extending along the first direction h1 and the second common line 3302 extending along the second direction h2.

Exemplarily, the type-III common line 33 can be electrically connected to part of the type-I common line 31 described above. The type-III common line 33 does not cross the edge connecting line.

Exemplarily, as shown in FIG. 1, the display area AA includes a first area Q81 and a second area Q82 located between the light transmission area TA and the binding area BA. A distance between the first area Q81 and the second area Q82 is greater than a distance between the second area Q82 and the binding region BA. The first region Q81 includes the type-III common line 33. The second region Q82 does not comprise type-III common line.

Exemplarily, in some embodiments of the present disclosure, the first common sub-line 3101 of the type-I common line 31 and the first common sub-line 3301 of the type-III common line 33 are disposed in a same layer, and the second common sub-line 3102 of the type-I common line 31 and the second common sub-line 3302 of the type-III common line 33 are disposed in a same layer, so as to simplify the manufacturing process of the display panel, and reduce the number of layers in the display panel.

Optionally, as shown in FIG. 3, the first common sub-line 3101 and the second common sub-line 3102 in the type-I common line 31 are electrically connected through the first connecting hole 71. The first connecting hole 71 penetrates through the insulation layer between the first common sub-line 3101 and the second common sub-line 3102.

As shown in FIG. 31, the first common sub-line 3301 and the second common sub-line 3302 of the type-III common line 33 are electrically connected through the second connecting hole 72. The second connecting hole 72 penetrates through the insulation layer between the first common sub-line 3301 and the second common sub-line 3302.

Exemplarily, when the first common sub-line 3101 and the first common sub-line 3301 are located in the fourth metal layer M4, and the second common sub-line 3102 and the second common sub-line 3302 are located in the fifth metal layer M5, the first connecting hole 71 and the second connecting hole 72 penetrate through the fifth insulation layer IS5.

In some embodiments of the present disclosure, the arranging direction of at least part of the first connecting holes 71 in multiple first connecting holes 71 is parallel to that of at least part of the second connecting holes 72 in multiple second connecting holes 72; and/or, in the same direction, the distance between at least part of two adjacent first connecting holes 71 is the same as the distance between at least part of two adjacent second connecting holes 72. Exemplarily, as shown in FIG. 3 and FIG. 31, in some embodiments of the present disclosure, at least part of the second connecting holes 72 is translated to coincide part of the first connecting holes 71, to improve distribution uniformity of connecting holes at different positions of the display area AA.

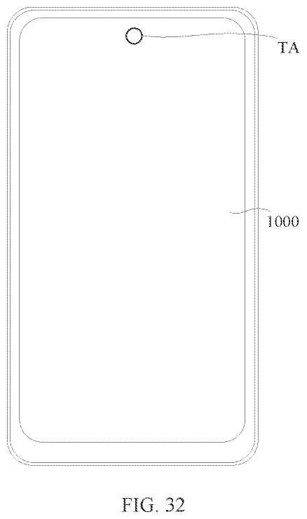

The present disclosure further provides a display apparatus. FIG. 32 is a schematic diagram of a display apparatus according to an embodiment of the present disclosure. As shown in FIG. 32, the display apparatus includes the display panel 1000 described above. The specific structure of the display panel 1000 has been explained in detail in the above embodiments, which will not be repeated here. It can be appreciated that the display apparatus shown in FIG. 32 is only a schematic illustration. The display apparatus can be any electronic device with display function, such as a mobile phone, a tablet computer, a laptop computer, an electronic paper book, or a television. Optionally, the display apparatus further includes a photosensitive element disposed by corresponding to the transmission area TA.

The above are merely some embodiments of the present disclosure, which, as described above, are not configured to limit the present disclosure. Whatever within the principles of the present disclosure, including any modification, equivalent substitution, improvement, etc., shall fall into the protection scope of the present disclosure.

What is claimed is:

1. A display panel, comprising:
a display area; and a light transmission area at least partially surrounded by the display area; wherein the display area comprises:
signal lines arranged along a first direction and each extending along a second direction, wherein the first direction intersects with the second direction;
connecting lines configured to electrically connect the signal lines located at two sides of the light transmission area along the second direction, wherein the connecting lines comprise type-I connecting lines, and at least part of the type-I connecting lines is located in the display area; the type-I connecting lines comprise an edge connecting line, and the edge connecting line, as one of the type-I connecting lines, has a maximum distance from the light transmission area; and
common lines comprising type-I common lines, wherein at least part of the type-I common lines is located in the display area, and part of the type-I common lines is located at a side of the edge connecting line adjacent to the light transmission area.

2. The display panel according to claim 1, wherein
the type-I common lines comprise a first common line insulated from and crossed with the edge connecting line;
the display area comprises a first pixel driving circuit and a second pixel driving circuit that are arranged adjacent to each other along an extension direction of the first common line, and the first pixel driving circuit and the second pixel driving circuit are located at a side of the edge connecting line adjacent to the light transmission area; and
the first common line overlaps with the first pixel driver circuit, and at least part of the type-I connecting lines parallel to the first common line overlaps with the second pixel driving circuit.

3. The display panel according to claim 1, wherein
the type-I common lines comprise a second common line insulated from and crossed with the edge connecting line; and
the display area comprises at least one first pixel driving circuit group, the first pixel driving circuit group comprises pixel driving circuits arranged along an extension direction of the second common line; along a direction perpendicular to a plane of the display panel, the at least one first pixel driving circuit group overlaps with the second common line and does not overlap with part of the type-I connecting lines parallel to the second common line.

4. The display panel according to claim 3, wherein
the type-I connecting lines comprise a first connecting line, a second connecting line and a third connecting line that are adjacent to one another;
part of the second connecting line parallel to the second common line is located between part of the first connecting line parallel to the second common line and part of the third connecting line parallel to the second common line;
a distance between part of the second connecting line parallel to the second common line and part of the first connecting line parallel to the second common line is greater than a distance between part of the second connecting line parallel to the second common line and part of the third connecting line parallel to the second common line; and
the second common line is located between part of the first connecting line parallel to the second common line and part of the second connecting line parallel to the second common line.

5. The display panel according to claim 4, wherein
a distance between the second common line and part of the first connecting line parallel to the second common line is greater than or equal to the distance between part of the second connecting line parallel to the second common line and part of the third connecting line parallel to the second common line;
and/or,
a distance between the second common line and part of the second connecting line parallel to the second common line is greater than or equal to the distance between part of the second connecting line parallel to the second common line and part of the third connecting line parallel to the second common line.

6. The display panel according to claim 1, wherein
the display panel comprises at least two light transmission areas including the light transmission area; and
the common lines further comprise a third common line, and at least part of the third common line is located between two adjacent light transmission areas of the at least two light transmission areas.

7. The display panel according to claim 6, wherein the display area comprises a first display sub-area located between two adjacent light transmission areas, the first display sub-area comprises a pixel driving circuits arranged along an arranging direction of two adjacent light transmission areas, x first connecting lines along the arranging direction of two adjacent light transmission areas, y third common lines along the arranging direction of two adjacent light transmission areas; where, x+y≤a; and
the two adjacent light transmission areas are arranged along the first direction or the second direction.

8. The display panel according to claim 6, further comprising a first non-display area partially surrounding the display area;
wherein the light transmission area adjacent to the first non-displaying area comprises a first end and a second end, the first end is located at a side of one light transmission area adjacent to another light transmission area, and the second end is located at a side of the light transmission area adjacent to the first non-displaying area; and
the signal lines comprise a first signal line; a distance between the first signal line and the first end is smaller than a distance between the first signal line and the second end; and
part of the type-I connecting lines that is electrically connected to the first signal line is located between the second end and the first non-display area.

9. The display panel according to claim 1, wherein
the type-I connecting lines comprise a fourth connecting line and a fifth connecting line, and the light transmission area is located between the fourth connecting line and the fifth connecting line; and
the type-I common lines further comprise a fourth common line located between the fourth connecting line and the fifth connecting line.

10. The display panel according to claim 1, wherein
the light transmission area comprises at least two light transmission sub-areas;
the display panel further comprises a second non-display area located between two adjacent light transmission sub-areas; and
the type-I common lines comprise a fifth common line, and at least part of the fifth common line is located in the second non-display area.

11. The display panel according to claim 10, wherein
part of the fifth common line extends from the display area to the second non-display area.

12. The display panel according to claim 11 wherein
another part of the fifth common line terminates at an edge of the second non-display area.

13. The display panel according to claim 12, further comprising sub-pixels, wherein one of the sub-pixels comprise a pixel driving circuit and a light-emitting element that are electrically connected to each other; and
in the second non-display area, the part of the fifth common line that extends from the display area to the second non-display area and the another part of the fifth common line that terminates at the edge of the second non-display area are located in a same layer and are adjacent to each other, and
a distance between the part of the fifth common line that extends from the display area to the second non-display area and the another part of the fifth common line that terminates at the edge of the second non-display area is smaller than or equal to a width of one pixel driving circuit of the pixel driving circuits.

14. The display panel according to claim 10, wherein
the second non-display area comprises a dummy pixel, the dummy pixel partially overlaps with the fifth common line along a direction perpendicular to a plane of the display panel.

15. The display panel according to claim 14, wherein
one of the sub-pixels comprises a pixel driving circuit, a connecting electrode and a light-emitting element;
the pixel driving circuit is electrically connected to the light-emitting element through the connecting electrode; the dummy pixel does not comprise a connecting electrode; and
at least part of the fifth common line is disposed in a same layer as the connecting electrode.

16. The display panel according to claim 14, wherein
one of the sub-pixels comprises a light-emitting element; the dummy pixel does not comprise a light-emitting element; and at least part of the fifth common line is located in a same layer as the electrode of the light-emitting element in the one of the sub-pixels.

17. The display panel according to claim 10, wherein
the connecting lines further comprise a type-II connecting line located at a side of the second non-display area adjacent to the light transmission sub-area, and the type-II connecting line partially surrounds the light transmission sub-area.

18. The display panel according to claim 1, further comprising a first non-display area, wherein the first non-display area at least partially surrounds the display area; and
the first non-display area comprises a common bus electrically connected to the type-I common lines.

19. The display panel according to claim 18, wherein
part of the type-I connecting lines and part of the type-I common lines are located in the first non-display area; and
in the first non-display area, the type-I common lines partially overlap with the type-I connecting lines along a direction perpendicular to a plane of the display panel.

20. The display panel according to claim 1, wherein
the type-I connecting lines comprise a first connecting sub-line and a second connecting sub-line that are crossed with and electrically connected to each other;
the type-I common lines comprise a first common sub-line and a second common sub-line that are crossed with and electrically connected to each other;
the first connecting sub-line and the first common sub-line are parallel to each other and disposed in a same layer; and
the second connecting sub-line and the second common sub-line are parallel to each other and disposed in a same layer.

21. The display panel according to claim 1, further comprising a type-II common line located at a side of the light transmission area adjacent to the display area;
wherein the type-II common line at least partially surrounds the light transmission area; and the type-II common line is electrically connected to the type-I common line; and the type-II common line and the type-I common line that are electrically connected to each other are disposed in a same layer; or in a direction perpendicular to a plane of the display panel, an insulation layer is provided between the type-II common line and the type-I common line, the insulation layer comprises a through hole through which the type-II common line and the type-I common line are electrically connected to each other.

22. The display panel according to claim 21, wherein
an orthographic projection of the type-II common line on a plane of the display panel has a zigzag shape or a ring shape.

23. The display panel according to claim 1, further comprising a first supply voltage line, a second supply voltage line and a reference voltage line that are electrically connected to the pixel driving circuit;
wherein the first supply voltage line is configured to transmit a first supply voltage, a second supply voltage line is configured to transmit a second supply voltage, and the reference voltage line is configured to transmit a reference voltage; and
signals transmitted by the common lines comprise one of the first supply voltage, the second supply voltage or the reference voltage.

24. The display panel according to claim 1, wherein
the common lines further comprise a type-III common line, part of the type-III common line is located at a side of the edge connecting line away from the light transmission area.

25. The display panel according to claim 24, wherein
the common lines comprise a first common sub-line and a second common sub-line that are crossed with and electrically connected to each other;
the first common sub-line and the second common sub-line in the type-I common line are electrically connected to each other through first connecting holes;
the first common sub-line and the second common sub-line in the type-III common line are electrically connected to each other through second connecting holes; and
an arranging direction of the first connecting holes and an arranging direction of the second connecting holes are parallel to each other; and/or, in a same direction, a distance between two adjacent first connecting holes is the same as a distance between two adjacent second connecting holes.

26. The display panel according to claim 1, wherein
the signal lines comprises a data line;
the type-I connecting lines comprise a first connecting sub-line and a second connecting sub-line that are crossed with and electrically connected to each other; and
an extension direction of the second connecting sub-line and an extension direction of the data line are parallel to each other, and the second connecting sub-line and the data line are disposed in a same layer.

27. The display panel according to claim 26, wherein
the display area comprises sub-pixels, and one of the sub-pixels comprises a pixel driving circuit and a light-emitting element that are electrically connected to each other; the pixel driving circuit comprises a drive transistor electrically connected to a first node; and
the display panel further comprises a first shielding layer, the first shielding layer at least partially overlaps with the first node along a direction perpendicular to a plane of the display panel.

28. The display panel according to claim 27, wherein
the first shielding layer is disposed in a same layer as the first connecting sub-line.

29. A display apparatus, comprising a display panel, wherein the display panel comprises a display area and a light transmission area at least partially surrounded by the display area; wherein the display area comprises:
signal lines arranged along a first direction and each extending along a second direction, wherein the first direction intersects with the second direction;
connecting lines configured to electrically connect the signal lines located at two sides of the light transmission area along the second direction, wherein the connecting lines comprise type-I connecting lines, and at least part of the type-I connecting lines is located in the display area; the type-I connecting lines comprise an edge connecting line, and the edge connecting line, as one of the type-I connecting lines, has a maximum distance from the light transmission area; and
common lines comprising type-I common lines, wherein at least part of the type-I common lines is located in the display area, and part of the type-I common lines is located at a side of the edge connecting line adjacent to the light transmission area.
